(19) United States
(12) Patent Application Publication
(10) Pub. No.: US 2024/0405158 A1
(43) Pub. Date: Dec. 5, 2024

(54) LIGHT EMITTING DIODES CONTAINING EPITAXIAL LIGHT CONTROL FEATURES

(71) Applicant: The Regents of the University of California, Oakland, CA (US)

(72) Inventors: Srinivas Gandrothula, Ibaraki (JP); Shuji Nakamura, Santa Barbara, CA (US); Steven P. DenBaars, Goleta, CA (US)

(73) Assignee: The Regents of the University of California, Oakland, CA (US)

(21) Appl. No.: 18/701,367

(22) PCT Filed: Oct. 28, 2022
(86) PCT No.: PCT/US22/48233

§ 371 Date: Apr. 15, 2024

Related U.S. Application Data
(60) Provisional application No. 63/273,321, filed on Oct. 29, 2021.

(51) Int. Cl. H01L 33/10; H01L 33/00; H01L 33/22

(52) U.S. Cl. CPC H01L 33/105; H01L 33/007; H01L 33/22; H01L 2933/0083

(57) ABSTRACT

A method for fabricating epitaxial light control features, without reactive ion etching or wet etching, when active layers are included. The epitaxial light control features comprise light extraction or guiding structures integrated on an epitaxial layer of a light emitting device such as a light emitting diode. The light extraction or guiding structures are fabricated on the epitaxial layer using an epitaxial lateral overgrowth (ELO) technique. The epitaxial light control features can have many different shapes and can be fabricated with standard processing techniques, making them highly manufacturable at costs similar to standard processing techniques.

### CROSS REFERENCE TO RELATED APPLICATIONS

This application claims the benefit under 35 U.S.C. Section 119 (e) of the following co-pending and commonly-assigned application:
U.S. Provisional Application Ser. No. 63/273,321, filed on Oct. 29, 2021, by Srinivas Gandrothula, Shuji Nakamura, and Steven P. DenBaars, entitled “LIGHT EMITTING DIODES CONTAINING EPITAXIAL LIGHT CONTROL FEATURES,” Attorney's Docket Number G&C 30794.0811USP1 (UC 2022-769-1);
which application is incorporated by reference herein.

### BACKGROUND OF THE INVENTION

### 1. Field of the Invention

This invention is directed to light emitting diodes (LEDs) of micro-size to macro-size with epitaxial light control features, and more particularly, to high-efficiency LEDs with photonic crystal (PhC) light extractors.

### 2. Description of the Related Art

The past 30 years have seen significant development for III-nitride LEDs. There are two approaches for increasing efficiency of III-nitride LEDs: the first is increasing the internal quantum efficiency (IQE), which is determined by the crystal quality of the epitaxial layer structure, and the second is increasing light extraction efficiency (EQE).

IQE in III-nitride LEDs has been greatly improved (more than 80%) by the availability of low-dislocation GaN substrates (which have defect densities in the mid 10⁶ dislocations per cm²), and advances in metal organic chemical vapor deposition (MOCVD) techniques. When device layers' defect densities are reduced further below 10⁶ dislocations per cm², IQE will improve.

C-plane III-nitride devices have been reported with greatly improved EQE and output power using surface roughening methods, such as the use of a patterned Sapphire substrate (PSS) and photoelectrochemical (PEC) etching techniques. Moreover, the roughened devices demonstrate better performance by having an improved output power after packaging, as compared with conventional devices, mainly due to the dramatic enhancement of photon extraction from the backside of the substrate.

The effectiveness of this patterning technique by and large depends on the crystal orientation and polarity of the to-be-patterned surface. So far, it has only been established for the nitrogen-face of a c-polar GaN [Appl. Phys. Lett. 84, 855 (2004)], but not for arbitrary GaN crystal orientations and polarity, including most semipolar surfaces and nonpolar a-plane and m-plane surfaces.

Reactive ion etching (RIE) is another technique to pattern conical features to enhance light extraction irrespective of crystal orientation [Applied Physics Express 9, 102102 (2016)].

The advantage of surface roughening is that there are many available techniques to create the random roughened surfaces. However, the random characteristic of photon dynamics is less controllable for beam shaping. The use of a microlens array or a PhC array with regular periodic structures not only enhances the light out-coupling but also provides the capability to tune the angular intensity distribution.

Improving the directionality of light emission has been widely studied either through the use of microcavities or PhCs. The very promising application of PhC structures is used to control the propagation of electromagnetic modes in optoelectronic devices. The periodic modulation of refraction serves as an optical grating to couple guided modes from the semiconductor device to air, thus increasing extraction efficiency and directionality of LEDs. The application of gratings for light diffraction in optoelectronic devices requires the grating period to be on the order of half of the wavelengths of the light generated by the device. In the case of GaN-based optoelectronic devices, the grating period needs to be on the order of a few hundreds of nanometers.

The main difficulty with PhC LEDs is their required delicate fabrication. The main challenge in fabricating PhC LEDs is the need for defining the PhC pattern with its features on a wavelength scale, i.e., a hole radius of 100-1000 nm for the visible spectrum. Commonly used lithography techniques, such as contact lithography, are limited to feature sizes of about 1 μm by the diffraction limit or are extremely expensive, such as deep-UV lithography.

On an R&D level, e-beam lithography is widely used to define the PhC pattern into an appropriate resist. After the resist is developed, it serves as an etching mask to transfer the pattern into the semiconductor. Even though e-beam lithography is capable of fabricating feature sizes down to 20 nm along with arbitrary patterns, it is not applicable to mass production due to its extremely low throughput.

A very promising patterning technique is nano-imprint technology. First, a stamp with an inverse pattern is fabricated, which is known as a master. By pressure or capillary forces, the pattern is printed into a resist already cast upon the LED surface. After heating and/or UV-curing, the stamp is removed and the resist can act as an etching mask. The patterning process can be done on a wafer-scale and thus offers high throughput. As the master has to be fabricated first by conventional techniques, like e-beam lithography, it is less flexible; however, arbitrary patterns with feature sizes on the order of 10-20 nm can be printed.

Thus, there is a need in the art for improved light control features for LEDs. This invention satisfies that need.

### SUMMARY OF THE INVENTION

This invention focuses on providing light emitting devices with reduced defect density having integrated light control features to extract, guide, reflect, refract, focus or defocus light emitted from the devices. This invention epitaxially integrates the light control features directly onto an epitaxial layer of the devices.

The method described in this application is different from conventional PhC fabrication. In this invention, etching directly on semiconductor layers containing an active layer is avoided for PhC fabrication. Also, this invention allows for selecting either a random rough surface or an organized two-dimensional (2D) triangular periodic lattice for PhCs without exposing the light emitting device to physical etching methods, such as reactive ion, plasma or capacitively-coupled etching. The approach described in this invention mitigates possible etch-related damage to the quantum wells (QWs), since the patterning is formed epitaxially at the initial stage of the device layers' growth. Additionally, the IQE of the device is improved as the epitaxial layers are defect filtered through selective area growth (SAG), also referred to as epitaxial lateral overgrowth (ELO).

This invention is applicable to the fabrication of macro-sized to micro-sized LEDs. This invention can be modified for macro-sized LED applications (having a size of ˜100,000 μm²) or micro-sized LED applications (having a size of ˜1 μm²).

For example, next-generation displays, such as micrometer-sized LED displays, have been researched intensively, with their advantages of high wall-plug efficiency (WPE) and wide color gamut, as compared to conventional liquid crystal displays (LCDs) and organic LED (OLED) displays. However, there are several issues with conventional micrometer-thick micro-LEDs, such as color mixing, color purity, temperature, and color stability.

In order to solve these problems, III-nitride-based blue, green, and red PhC cavity micro-LEDs (PhC-Cavity-μLEDs) with a single mode emission are attracting more attention as potential alternatives. The advantages of PhC-Cavity-μLEDs are spectral purity and thermal stability because the spectrum width and shape are determined by the overlap of the cavity mode and the InGaN QW emission. Another advantage is that the emission of PhC-Cavity-μLEDs is more directional than conventional LEDs. These advantages suggest that PhC-Cavity-μLEDs could be the best fit for display applications.

Displays based on an array of μLEDs are also a promising technology for a wide range of applications. In these 2D arrays, each μLED works as a single pixel of a whole image. These μLED displays can be used in applications ranging from TVs, laptops, smartphones, heads-up displays (HUDs) and augmented reality/virtual reality/mixed reality (AR/VR/MR) applications. In these applications, directionality plays a major role as cross-correlation of light may degrade the picture quality.

This invention proposes the use of an ELO technique to obtain a defect-filtered crystalline quality (visibly no defects). The light emitting region is defined on the wings of the ELO region to guarantee a reduced defect region. Light control features are developed at the initial stage of the ELO by shaping either the growth restrict mask or the host substrate, to guarantee no physical damage to the QW region or the device layers' performance.

This invention starts by shaping a desired feature on a growth restrict mask deposited on a substrate and allowing the first ELO layers to take the shape of the desired feature epitaxially, wherein the first ELO layers usually serve as n-type layers for the device. This invention can be realized using a homogeneous host substrate, similar to the device layers' material, or can be realized using foreign substrates, such as Sapphire, Si, SiC, SiN, Ga₂O₃, LiAlO₂, etc., including substrates with III-nitride templates, such as ELO III-nitride templates. Alternatively, desired features can be formed on the host substrate before placing an ELO mask. In this scenario, when reusing the host substrate, feature forming steps can be avoided as the features remain intact when removing device layers from the host substrate.

The present invention focuses on the use of the III-nitride material system, which comprises alloy compositions of the chemical formula GaₓAl_{y}In_{z}N where 0≤x≤1, 0≤y≤1, 0≤z≤1, and x+y+z=1. While the majority of current research attention focuses on InGaN-based LEDs, there is some research on AlGaN LEDs emitting at UV-A wavelengths. Consequently, while this invention concentrates on InGaN LEDs, most of the techniques described herein should be applicable to AlGaN LEDs as well.

One of the most vital advantages of the InGaN material system is the emission wavelength tunability by varying the composition percentage of indium and gallium in the active region, since the bandgaps of GaN and InN are 3.4 eV and 0.7 eV, respectively, and alloys of the InGaN material system can theoretically cover the entire visible spectrum.

Additionally, current InGaN materials, especially for display applications, are grown on Sapphire or Silicon (Si) substrates using MOCVD. Depending on the reactor dimensions, the wafer diameter can be scaled from 2-inches to 6-inches for Sapphire substrates, or up to 18-inches for Si substrates, and this scalability is ideal for mass production with low material cost.

The approach of this invention uses the ELO technique, which in principle can be adapted to any of the above-mentioned substrates, and thus scalability is not a problem in applying the techniques of this invention. Additionally, the light emitting area of the device comprises a wing region of the ELO layers, which is known for better crystal quality as compared to growing device layers directly on the substrates or their templates. Therefore, increased efficiency would be possible by following the approach of this invention.

Conventional LEDs (with at least one side larger than 300 μm) usually have a large light emitting area on top of the device to reduce carrier concentration in the active region and to avoid the influences of efficiency droop. Due to this large light emitting area, non-radiative centers, such as crystal defects, may not play a major role in device operation. However, when the light emitting area is on the order of 100 μm×100 μm to 10 μm×10 μm, or even smaller, existing defects in the active region may significantly degrade the performance. The present invention solves these problems, even on homogeneous substrates, providing for better crystal qualities and improved efficiencies.

To overcome the limitations in the prior art described above, and to overcome other limitations that will become apparent upon reading and understanding this specification, the present invention discloses a method for fabricating light control features, such as guiding or extracting features, epitaxially on device layers by patterning a growth restrict mask deposited on a host substrate, where the host substrate can be a III-nitride substrate, foreign substrate, or a III-nitride template deposited on a foreign substrate.

Specifically, this invention performs the following steps: island-like III-nitride semiconductor layers are grown on the substrate using the pre-patterned growth restrict mask and the ELO method, where the patterns on the growth restrict mask provide the desired light control features. III-nitride ELO layers are grown on the substrate, and then over the growth restrict mask. Fabrication of devices layers on the III-nitride ELO layers is performed at wings of the III-nitride ELO layers, which has good crystal quality in terms of dislocation densities and stacking faults. A light emitting aperture is confined to the wings of the III-nitride ELO layers, at least in part, such that good crystal quality layers can be guaranteed.

Front-end fabrication, such as mesa formation, and p-pad and n-pad processing, is performed on the wings of the III-nitride ELO layers, and then device units are plucked from the host substrate and placed on a carrier or submount. The devices can be removed from the substrate either by an elastomer stamp, or vacuum chuck, or an adhesive tape, or simply by bonding or attaching them to a separate carrier or submount.

Key aspects of this invention include the following:
Light extraction and/or directionality is controlled.
Light control features are placed on a backside of the III-nitride ELO layers, so that the p-side of the device, on the other side from the light extraction features, does not need to be thick, which is the case with many existing devices.
Roughening or periodic patterning on the device layers is performed without using a chemical etchant.
Roughening or periodic patterning on the device layers is performed without using physical etching.
Patterning features on the epitaxial layer, particularly on the n-GaN side of the device, avoids the need for thick p-GaN layers. Thick p-GaN layers are generally resistive, and any physical etching for light control features will damage device layers.
Low defect density epitaxial layers improve the electrical conductivity of subsequent p-GaN epitaxial layers grown thereon.
Patterning features near to the active region, e.g., in the vicinity of less than 25 μm, is performed without substantially including the host substrate.
Light control features are formed on wings of the III-nitride ELO layers, before the growth of the active region of the device.
This invention fabricates the light emitting area on wings of the III-nitride ELO layers, thereby providing better crystal quality in the light emitting area, which improves performance.
This invention can utilize foreign substrates, such as Sapphire, Si, SiC, SiN, Ga₂O₃, LiAlO₂, etc., including substrates with templates thereon, such as III-nitride templates, to scale up manufacturability for industrial needs.
This invention can be utilized to increase the yield by making smaller footprint devices confined to the wings of the III-nitride ELO layers.
Substrates can be recycled after the III-nitride ELO layers and device layers are removed, for a next batch of devices.
This method is independent of crystal orientations of the substrate.
Light control features can also be processed on the host substrate and then placement of ELO mask performed

A few of the possible designs using this method are illustrated in the following detailed description of the invention. The invention has many benefits as compared to conventionally manufacturable device elements when combined with the cross-referenced inventions on removing semiconducting devices from a semiconducting substrate set forth above.

### BRIEF DESCRIPTION OF THE DRAWINGS

Referring now to the drawings in which like reference numbers represent corresponding parts throughout:

FIGS. 1(a) and 1(b) are schematics of a substrate, growth restrict mask and different possible designs for the growth restrict mask, according to an embodiment of the present invention.

FIGS. 1(c) and 1(d) are schematics of III-nitride ELO layers and device layers grown from the patterned growth restrict mask, according to an embodiment of the present invention.

FIG. 2(a) is a step-by-step illustration of fabricating PhC patterns on a growth restrict mask for the subsequent growth of III-nitride ELO layers, according to an embodiment of the present invention.

FIG. 2(b) is a microscope image of colloids used to pattern a growth restrict mask.

FIG. 2(c) shows an atomic force microscopy (AFM) scan and two panchromatic cathode luminescence (CL) microscopy images of ELO III-nitride layers, when a planar growth restrict mask without any colloidal patterns was used.

FIG. 2(d) shows an AFM scan and two panchromatic CL microscopy images of ELO III-nitride layers, when a growth restrict mask with colloidal patterns was used.

FIG. 2(e) shows a scanning electron microscope (SEM) image and an AFM scan of the growth restrict mask with colloidal patterns.

FIG. 2(f) shows a microscope image of ELO III-nitride layers grown on a growth restrict mask with colloidal patterns, a SEM image of a portion of the ELO III-nitride layers, and an AFM scan of the portion of the ELO III-nitride layers.

FIG. 2(g) shows a SEM image and an AFM scan of a planar growth restrict mask without colloidal patterns.

FIG. 2(h) shows a microscope image of ELO III-nitride layers grown on a planar growth restrict mask, a SEM image of a portion of the ELO III-nitride layers, and an AFM scan of the portion of the ELO III-nitride layers.

FIG. 2(i) is a collection of microscope, SEM and AFM images of the front and backside of the III-nitride ELO layers for a planar growth restrict mask and a patterned growth restrict mask when different colloidal sizes were used to create the patterns.

FIGS. 3(a), 3(b) and 3(c) are schematics of a macro-size LED vertical pad configuration, according to an embodiment of the present invention.

FIGS. 3(c), 3(d) and 3(e) are schematics of a macro-size LED lateral pad configuration, according to an embodiment of the present invention.

FIGS. 4(a), 4(b), 4(c), 4(d), 4(e), 4(f), 4(g), 4(h), 4(i) and 4(j) illustrate the fabrication of micro-size LEDs with PhCs for display applications, according to an embodiment of the present invention.

FIGS. 5(a) and 5(b) are schematics that illustrate structures used to maximize vertical light extraction of PhC LEDs, according to an embodiment of the present invention.

FIGS. 6(a) and 6(b) are schematics that illustrate light extraction features epitaxially integrated on an n-side of a LED, according to an embodiment of the present invention.

FIGS. 7(a) and 7(b) are schematics that illustrate light extraction features epitaxially integrated on an n-side of a LED, according to an embodiment of the present invention.

FIG. 8 is a flow chart of a process to realize light emitting devices, according to an embodiment of the present invention.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

### Overview

The present invention describes a method of fabricating semiconductor devices, such as LEDs, by designing a growth restrict mask accordingly. Using ELO, this invention is easily applicable to homogenous substrates, such as GaN, or foreign substrates, such as Sapphire, Si, SiC, SiN, Ga₂O₃, LiAlO₂, etc., or templates on substrates.

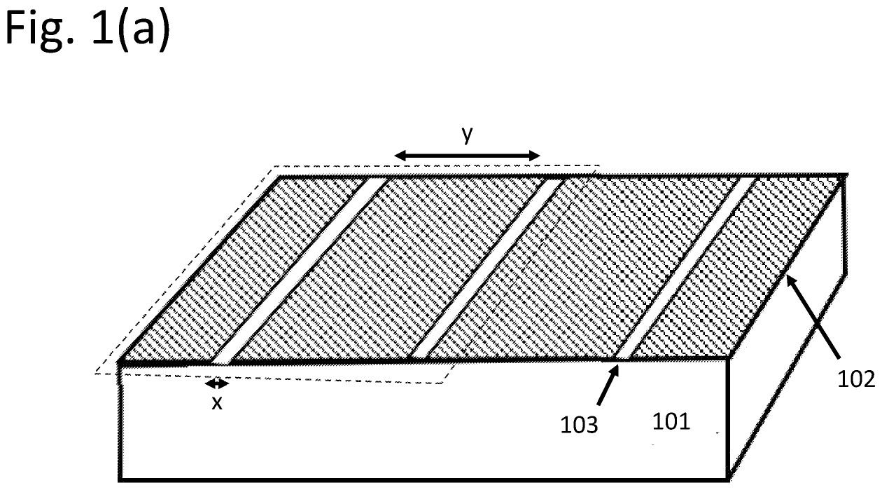

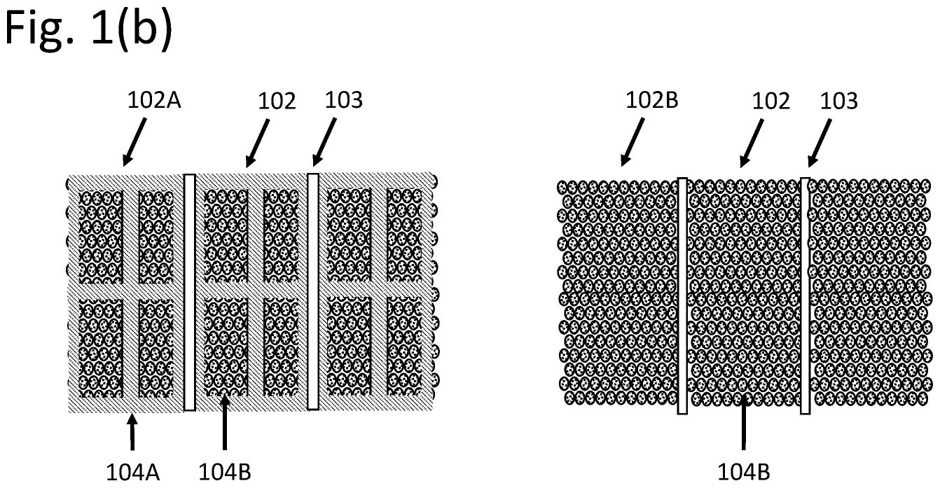

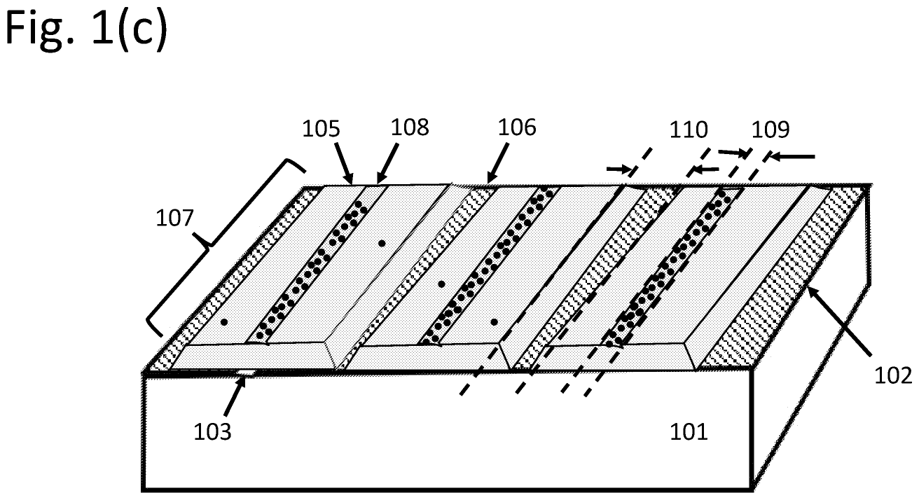

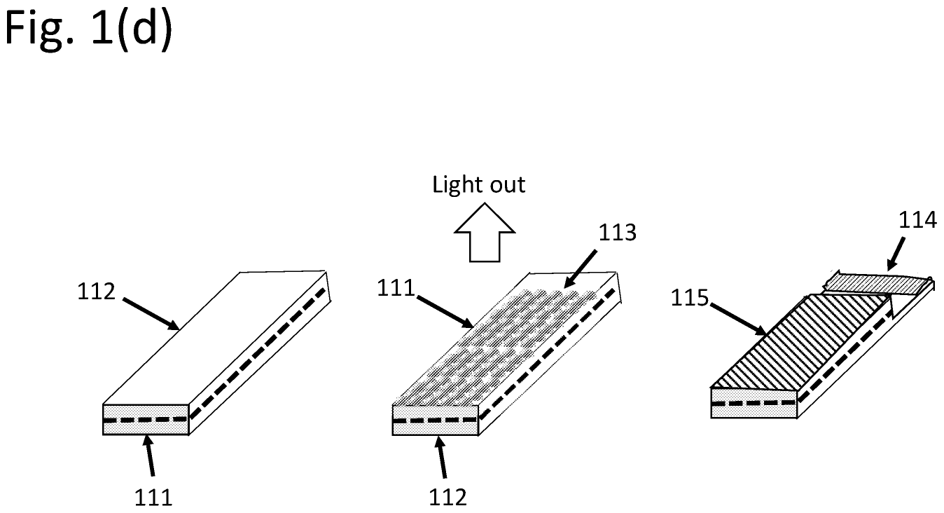

FIG. 1(a) illustrates an embodiment of the present invention, which comprises providing a III-nitride-based host substrate 101, such as a bulk GaN substrate 101, and then a growth restrict mask 102 is formed on the substrate 101. Specifically, the growth restrict mask 102 is disposed directly in contact with the substrate 101 or is disposed indirectly through an intermediate layer grown by MOCVD, etc., which is a template made of III-nitride-based semiconductor deposited on the substrate 101. The present invention can use SiO₂, SiN, SiON, TiN, etc., as the growth restrict mask 102, but is not limited to those materials.

The growth restrict mask 102 is deposited upon the host substrate 101, and is etched to form opening areas 103, wherein the remaining portions of the growth restrict mask 102 contain nanometer-scale patterns. The opening areas 103 have a width x and separate the remaining portions of the growth restrict mask 102 with the nanometer-scale patterns having a width of y.

Photo mask lithography and etching may be performed to create the opening areas 103, as well as no-growth regions (not shown). Alternatively, plasma chemical vapor deposition (CVD), sputter, ion beam deposition (IBD), etc., can also be used.

The nanometer-scale patterns may be formed on the growth restrict mask 102 using a technique called colloidal lithography [J. Vac. Sci. Technol., B 35, 011201 (2017)]. Alternatively, nanoimprinting, e-beam lithography, holography, interference lithography, etc., can be used.

Two designs for the growth restrict mask 102 are proposed in FIG. 1(b), namely, a hybrid mask 102A or a patterned mask 102B, wherein the hybrid mask 102A is a combination of smooth regions 104A and patterned regions 104B, and the patterned mask 102B is comprised of patterned regions 104B without smooth regions 104A.

FIG. 1(c) further illustrates the embodiment of FIG. 1(a), wherein epitaxial III-nitride layers 105, such as n-type GaN-based layers 105, are grown by ELO on the GaN substrate 101 and the growth restrict mask 102. The growth of the ELO III-nitride layers 105 occurs first in the opening areas 103 on the GaN-based substrate 101, and then laterally from the opening areas 103 over the growth restrict mask 102.

In one embodiment, the growth of the ELO III-nitride layers 105 is stopped or interrupted before the ELO III-nitride layers 105 at adjacent opening areas 103 can coalesce on top of the growth restrict mask 102, resulting in a no-growth region 106. In another embodiment, the growth of the ELO III-nitride layers 105 at adjacent opening areas 103 coalesces on top of the growth restrict mask 102.

Additional III-nitride semiconductor device 107 layers are deposited on or above the ELO III-nitride layers 105, and may include an active region, p-type layer, electron blocking layer (EBL), and cladding layer, as well as other layers. This results in a device 107 shaped as a bar.

Defects can be filtered when the ELO method is used. An illustration of dislocations are also shown in FIG. 1(c), where defects 108 in the growth of the ELO III-nitride layers 105 from the opening areas 103 originate from the host substrate 101, while wing regions in the ELO III-nitride layers 105 on either side of the defects 108 are visually defect-free.

A light-emitting region of the device 107 is processed on either side of an open region 109, preferably between the opening area 103 and the no-growth region 106. By doing so, each bar of a device 107 will possess an array of twin or nearly identical light emitting apertures (not shown) on either side of the open region 109 along the length of the bar. Alternatively, the open region 109 may be etched to create separate devices 107 along the bar, with each of the devices 107 possessing one or more light emitting apertures (not shown) on one side of the open region 109 along the length of the bar.

The III-nitride devices 107 may be separated from the host substrate 101 by etching a region 110 between neighboring bars, to expose at least the growth restrict mask 102. The region 110 also may be etched to separate the bars of devices 107 from adjacent bars of devices 107.

Moreover, this invention proposes several approaches in order to realize light control features for the light emitting devices 107. The typical fabrication steps for this invention are described in more detail below.

Step 1: Start with forming a desired shape on growth restrict mask 102, which can be achieved with the following. Place a growth restrict mask 102 on a host substrate 101. The growth restrict mask 102 is patterned either using nano-imprint lithography, or a desired shape can be transferred onto a growth restrict mask 102 using photolithography plus wet etching, or photolithography plus dry etching, or colloidal lithography.

Step 2: A plurality of striped opening areas 103 are opened on the substrate 101, wherein the substrate 101 is a III-nitride-based semiconductor, or the substrate 101 is a hetero-substrate, such as Sapphire, Si, SiC, SiN, Ga₂O₃, LiAlO₂, etc., or the substrate 101 includes a template prepared using the growth restrict mask 102.

Step 3: A plurality of ELO III-nitride layers 105 are grown on the substrate 101 using the growth restrict mask 102, such that the growth extends in a direction parallel to the striped opening areas 103 of the growth restrict mask 102. The ELO III-nitride layers 105 take the shape of a designed pattern (not shown) on the growth restrict mask 102 and the designed pattern is transferred to an interface between the ELO III-nitride layers 105 and the growth restrict mask 102.

Step 4: A light emitting device 107, such as an LED, is fabricated on wing regions of the ELO III-nitride layers 105, that is mostly covered by a flat surface region, by conventional lithography methods.

Step 5: The devices 107 are divided and isolated on the host substrate 101.

Step 6: A submount is attached to the devices 107.

Step 7: The growth restrict mask 102 and any protection layers used are dissolved using a chemical etchant, such as hydrofluoric acid (HF) or buffered hydrofluoric acid (BHF).

Step 8: The devices 107 are separated from the host substrate 101.

Step 9: The resulting devices 107 are packaged.

### Forming a Growth Restrict Mask

In one embodiment, the III-nitride layers 105, which may be GaN-based layers, are grown by ELO on a III-nitride substrate 101, such as an m-plane GaN substrate 101, and patterned with a growth restrict mask 102 comprised of SiO₂, wherein the ELO III-nitride layers 105 may or may not coalesce on top of the growth restrict mask 102.

The growth restrict mask 102 is comprised of striped opening areas 103 with a width x, wherein the SiO₂ stripes of the growth restrict mask 102 between the opening areas 103 have a width y of 1-20 μm and an interval of 10-100 μm. If a nonpolar substrate 101 is used, the opening areas 103 are oriented along a <0001> axis. If a semipolar (20-21) or (20-2-1) substrate 101 is used, the opening areas 103 are oriented in a direction parallel to [−1014] or [10-14], respectively. Other planes may be use as well, with the opening areas 103 oriented in other directions.

When using a III-nitride substrate 101, the present invention can obtain high quality ELO III-nitride layers 105. As a result, the present invention can also easily obtain devices 107 with reduced defect density, such as reduced dislocation and stacking faults.

Moreover, these techniques can be used with a hetero-substrate 101, such as Sapphire, Si, SiC, SiN, Ga₂O₃, LiAlO₂, etc., as long as it enables growth of the ELO III-nitride layers 105 through the growth restrict mask 102.

### Pattern the Growth Restrict Mask

Before etching the opening areas 103 on the growth restrict mask 102, a pre-process is performed on the growth restrict mask 102 to form one or more desired patterns of the light control features for light extraction or controllability.

FIG. 1(d) illustrates one embodiment that may be used with two different designed patterns, although other designed patterns may be used as well. In this embodiment, a first designed pattern is defined to enhance light extraction from macro-LEDs, and a second designed pattern is defined to enhance the directionality of emitted light using a photonic crystal (PhC) cavity.

In both instances, the device 107 includes both an n-side surface 111 and a p-side surface 112, wherein the designed patterns 113 are fabricated on the n-side surface 111, which is a light emitting surface. Device 107 fabrication is performed on the p-side surface 112, including n-pad 114 and p-pad 115 deposition.

### Growing Epitaxial Layers on the Substrate Using the Growth Restrict Mask

III-nitride semiconductor device 107 layers are grown on or above the ELO III-nitride layers 105 in a flat surface region on the wings of the ELO III-nitride layers 105. In one embodiment, conventional methods are used for the epitaxial growth of III-nitride semiconductor device 107 layers, such as MOCVD. In one embodiment, the III-nitride semiconductor device 107 layers are separated from each other, because MOCVD growth of the ELO III-nitride layers 105 is stopped before adjacent ones of the ELO III-nitride layers 105 can coalesce. In another embodiment, the ELO III-nitride layers 105 are made to coalesce and later etching is performed to remove unwanted regions 110.

Trimethylgallium (TMGa), trimethylindium (TMIn) and triethylaluminium (TMAl) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl)magnesium (Cp₂Mg) are used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

### ELO of Limited Area Epitaxy (LAE) III-Nitride Layers

In the prior art, a number of pyramidal hillocks have been observed on the surface of m-plane III-nitride films following growth. See, for example, US Patent Application Publication No. 2017/0092810. Furthermore, a wavy surface and depressed portions have appeared on the growth surface, which made the surface roughness worse. This is a very severe problem. For example, according to some papers, a smooth surface can be obtained by controlling an off-angle (>1 degree) of the substrate's growth surface, as well as by using an N₂ carrier gas condition. These are very limiting conditions for mass production, however, because of the high production costs. Moreover, GaN substrates have a large fluctuation of off-angles to the origin from their fabrication methods. For example, if the substrate has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

The present invention solves these problems as set forth below:

1. The growth area is limited by the area of the growth restrict mask 102 from the edges of the substrate 101.

2. The substrate 101 is a nonpolar or semipolar III-nitride substrate 101 that has off-angle orientations ranging from −16 degrees to +30 degrees from the m-plane towards the c-plane and C-plane. Alternatively, the substrate 101 is a hetero-substrate with a III-nitride-based semiconductor layer deposited thereon, wherein the layer has an off-angle orientation ranging from +16 degrees to −30 degrees from the m-plane towards the c-plane.

3. The bar of the devices 107 has a long side that is perpendicular to an a-axis of the III-nitride-based semiconductor crystal.

4. During MOCVD growth, a hydrogen atmosphere can be used.

In this invention, it can be used a hydrogen atmosphere during a non-polar and a semi-polar growth. Using this condition is preferable because a hydrogen can prevent an excessive growth at the edge of the open area 103 from occurring in the initial growth phase.

Those results have been obtained by the following growth conditions.

In one embodiment, the growth pressure ranges from 60 to 760 Torr, although the growth pressure preferably ranges from 100 to 300 Torr to obtain a wide width for the island-like III-nitride semiconductor layers; the growth temperature ranges from 900 to 1200° C. degrees; the V/III ratio ranges from 10-30,000; the TMG is from 2-20 sccm; NH₃ ranges from 0.1 to 10 slm; and the carrier gas is only hydrogen gas, or both hydrogen and nitrogen gases. To obtain a smooth surface, the growth conditions of each plane needs to be optimized by conventional methods.

After growing for about 2-8 hours, the ELO III-nitride layers 105 had a thickness of about 1-50 μm and a bar width of about 50-150 μm.

### Fabricating the Device

The device 107 is fabricated at a flat surface region on the wings of the ELO III-nitride layers 105 by conventional methods, wherein various device 107 designs are possible. For example, only a front-end process, such as p-pads and n-pads, may be needed to realize an LED, which can be performed either along the length or width of the wings of the ELO III-nitride layers 105. Alternatively, the interface can be used as the n-pad 114 by disposing metal partially over the patterns 113, or by creating a space for the n-pad 114 via hybrid mask 102A usage.

### Forming a Structure for Separating Device Units

The aim of this step is to isolate the ELO III-nitride layers 105 and III-nitride semiconductor device 107 layers from the host substrate 101. At least two methods can be used to transfer the devices 107 onto a carrier or submount. In one method, using a selective etching mask, the ELO III-nitride layers 105 and III-nitride semiconductor device 107 layers are separated from the host substrate 101 by etching an open region 109 and the region 110 between neighboring bars, at least to expose the growth restrict mask 102. The dividing of the layers 105, 107 may also be performed via scribing by a diamond tipped scriber or laser scriber, for example, or using tools such as RIE or ICP (Inductively Coupled Plasma) etching, but is not limited to those methods, and other methods also can be used to isolate the devices 107.

The method described in [Srinivas Gandrothula et al., 2020 Appl. Phys. Express, 13, 041003] may be used, or alternatively, a supporting carrier, such as a submount, may be used to lift-off the fabricated devices 107 from the host substrate 101.

### Definitions of Terms

### III-Nitride-Based Substrate

The III-nitride-based substrate 101 may comprise any type of III-nitride-based substrate 101, as long as a III-nitride-based substrate enables growth of III-nitride-based semiconductor layers, through a growth restrict mask 102. This includes any GaN substrate 101 that is sliced on a {0001}, {11-22}, {1-100}, {20-21}, {20-2-1}, {10-11}, {10-1-1} plane, etc., or other plane, from a bulk GaN, and AlN crystal substrate.

### Hetero-Substrate

Moreover, the present invention can also use a hetero-substrate 101, such as Sapphire, Si, SiC, SiN, Ga₂O₃, LiAlO₂, etc. For example, a GaN template or other III-nitride-based semiconductor layer may be grown on a hetero-substrate 101, prior to the deposition of the growth restrict mask 102. The GaN template or another III-nitride-based semiconductor layer is typically grown on the hetero-substrate 101 to a thickness of about 2-6 μm, and then the growth restrict mask 102 is disposed on the GaN template or another III-nitride-based semiconductor layer.

### Growth Restrict Mask

The growth restrict mask 102 comprises a dielectric layer, such as SiO₂, SiN, SiON, Al₂O₃, AlN, AlON, MgF, ZrO₂, TiN etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

In one embodiment, the thickness of the growth restrict mask 102 is about 0.05-3 μm. The width of the growth restrict mask 102 is preferably larger than 5 μm, and more preferably, the width is larger than 10 μm. The growth restrict mask 102 may be deposited by sputter, electron beam evaporation, plasma-enhanced chemical vaper deposition (PECVD), ion beam deposition (IBD), etc., but is not limited to those methods.

On an m-plane free standing GaN substrate 101, the growth restrict mask 102 comprises a plurality of opening areas 103, which are arranged in a first direction parallel to the 11-20 direction of the substrate 101 and a second direction parallel to the 0001 direction of the substrate 101, periodically at intervals extending in the second direction. The length of the opening areas 103 is, for example, 200 to 35000 μm; the width is, for example, 2 to 180 μm; and the interval of the opening areas 103 is, for example, 20 to 180 μm. The width of the opening areas 103 is typically constant in the second direction, but may be changed in the second direction as necessary.

On a c-plane free standing GaN substrate 101, the opening areas 103 are arranged in a first direction parallel to the 11-20 direction of the substrate 101 and a second direction parallel to the 1-100 direction of the substrate 101.

On a semipolar (20-21) or (20-2-1) GaN substrate 101, the opening areas 103 are arranged in a direction parallel to [−1014] and [10-14], respectively.

Alternatively, a hetero-substrate 101 can be used. When a c-plane GaN template is grown on a c-plane Sapphire substrate 101, the opening area 103 is in the same direction as the c-plane GaN template.

When an m-plane GaN template is grown on an m-plane Sapphire substrate 101, the opening area 103 is same direction as the m-plane GaN template. By doing this, an m-plane cleaving plane can be used for dividing the bar 107 of the device with the c-plane GaN template, and a c-plane cleaving plane can be used for dividing the bar of the device 107 with the m-plane GaN template, which is preferable.

### III-Nitride-Based Semiconductor Layers

The ELO III-nitride layers 105 and the III-nitride semiconductor device 107 layers can include In, Al and/or B, as well as other impurities, such as Mg, Si, Zn, O, C, H, etc.

The III-nitride-based semiconductor device 107 layers generally comprise more than two layers, including at least one layer among an n-type layer, an undoped layer and a p-type layer. The III-nitride-based semiconductor device 107 layers specifically comprise a GaN layer, an AlGaN layer, an AlGaInN layer, an InGaN layer, etc. In the case where the device 107 has a plurality of III-nitride-based semiconductor device 107 layers, the distance between the III-nitride semiconductor device 107 layers adjacent to each other is generally 30 μm or less, and preferably 1 μm or less, but is not limited to these figures. A number of electrodes, according to the types of the semiconductor device 107, are disposed at predetermined positions.

### Semiconductor Device

The semiconductor device 107 may be, for example, a Schottky diode, a light-emitting diode, a semiconductor laser, a photodiode, a transistor, etc., but is not limited to these devices. This invention is particularly useful for micro-LEDs and VCSELs. This invention is especially useful for a semiconductor laser, which requires smooth regions for cavity formation.

### ALTERNATIVE EMBODIMENTS

The following describes alternative embodiments of the present invention.

### First Embodiment

A first embodiment comprises a III-nitride-based LED with light control features comprising an attached pattern for light extraction and/or guiding, as well as a method for manufacturing the LED. This embodiment is shown in FIGS. 1(a), 1(b), 1(c) and 1(d).

The host substrate 101 is provided and the growth restrict mask 102 that has a plurality of striped opening areas 103 is formed on the substrate 101.

In this embodiment, the growth restrict mask 102 is patterned to include structures comparable to the emitting wavelength, such as PhCs, for better light extraction. Alternatively, the same structures may be fabricated on the host substrate 101, and then the growth restrict mask 102 is laid over the fabricated structures and takes the shape of the structures.

For a proof of concept, a feasibility experiment was conducted to transfer a pattern onto an interface between the growth restrict mask 102 and the III-nitride ELO layers 105. Specifically, the hybrid mask 102A or the patterned mask 102B, also may be used.

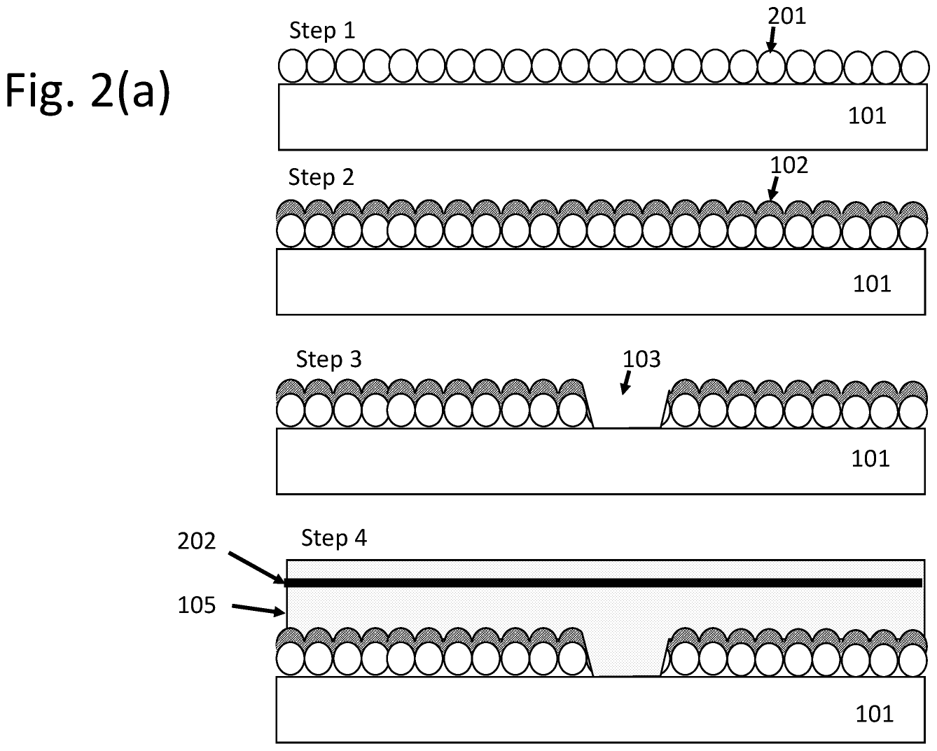

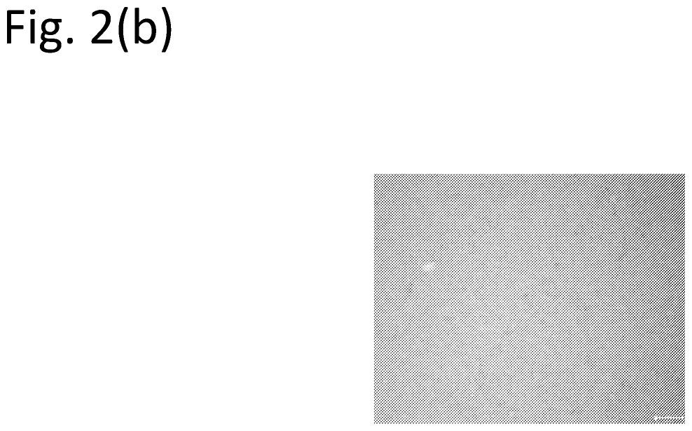

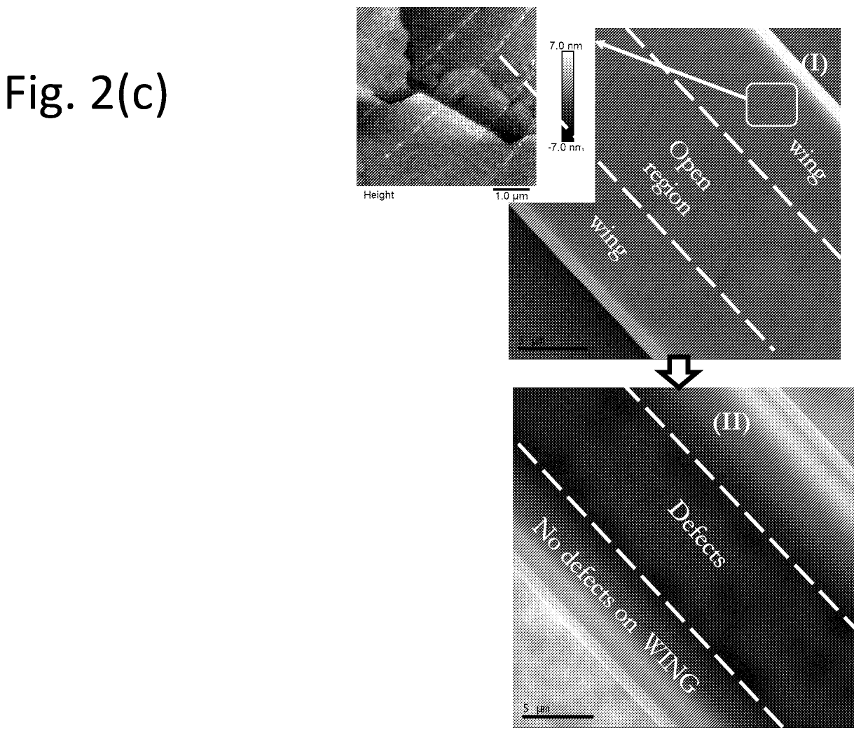

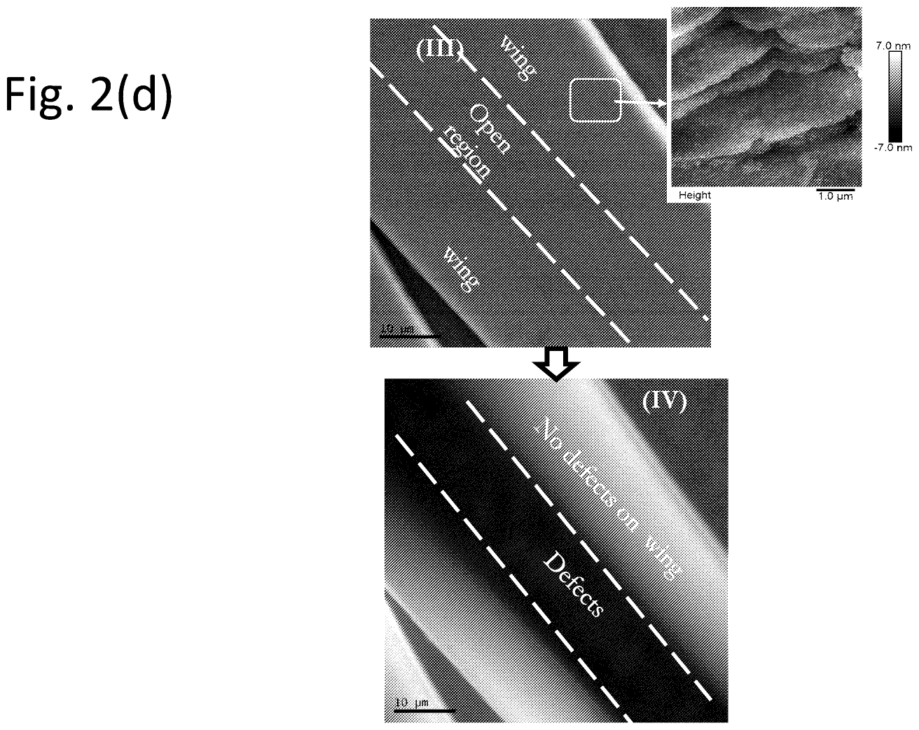

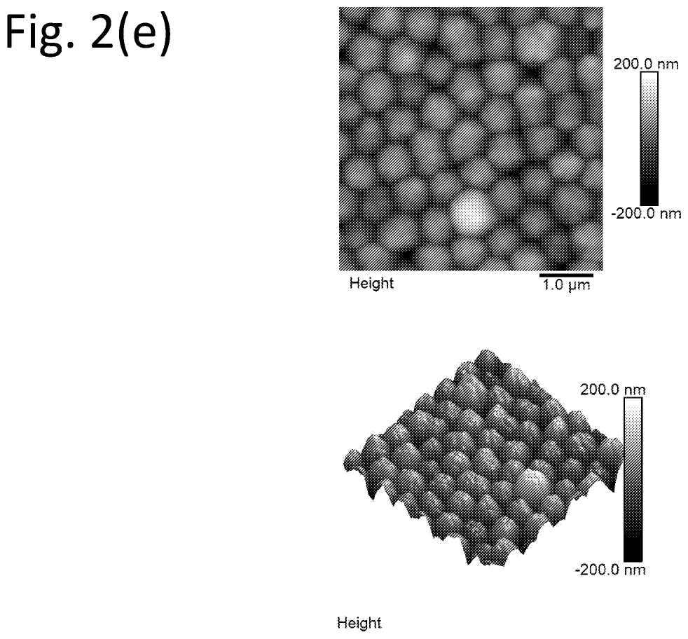

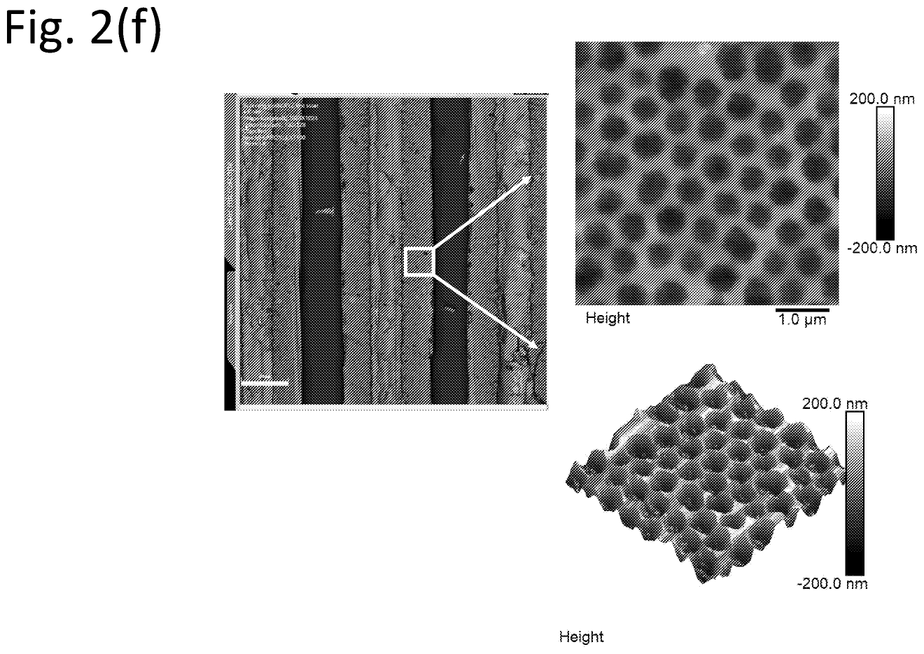

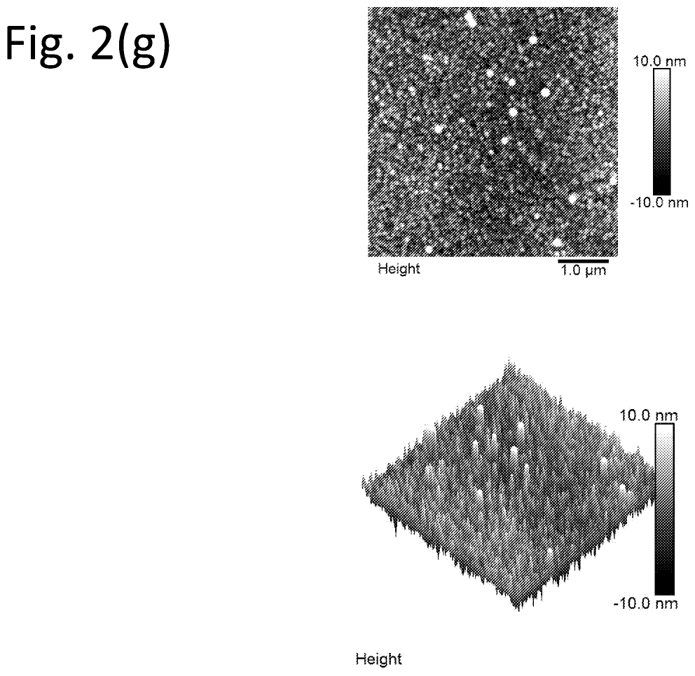

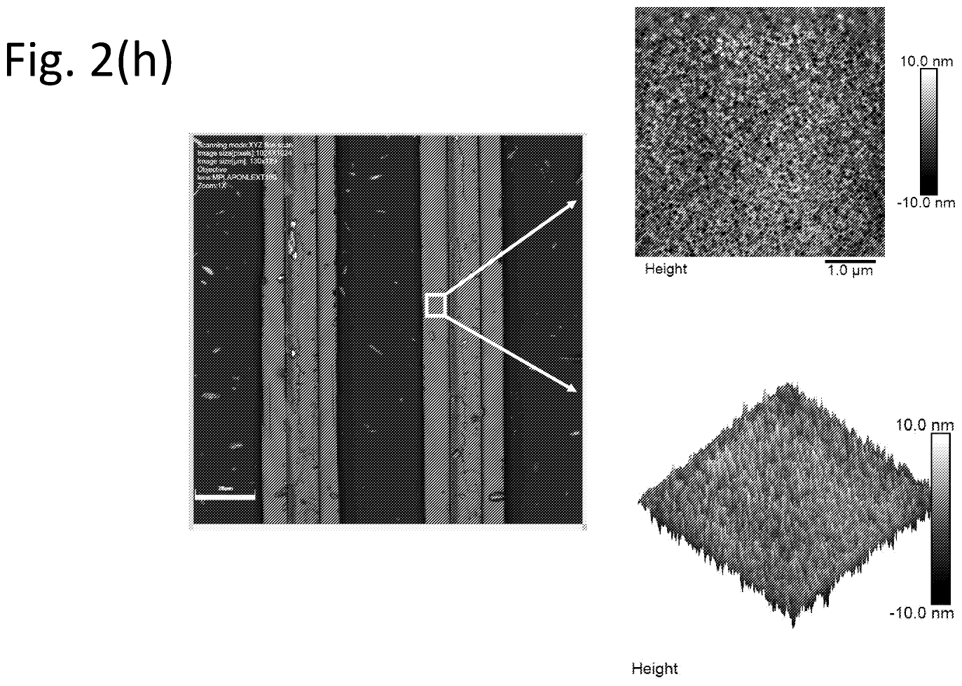

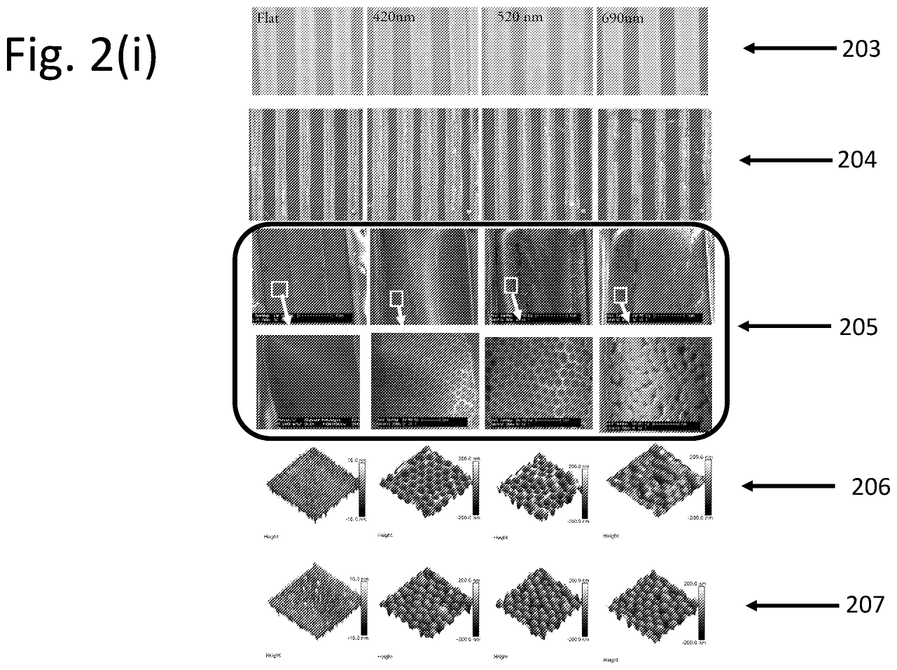

FIG. 2(a) illustrates the steps performed in the feasibility experiment. A GaN-on-Sapphire substrate 101 with a c-plane GaN template was used for this study. As shown in Step 1, a PhC pattern is deposited on the host substrate 101 using silica colloids 201, as described in [J. Vac. Sci. Technol., B 35, 011201 (2017)]. The average diameter size of the colloids 201 is ˜500 nm. A microscope image of the colloids 201, which average 420 nm in diameter, is shown in FIG. 2(b). Then, as shown in Step 2, a 500 nm thick SiO₂ layer comprising the growth restrict mask 102 was deposited using PECVD.

Two mask patterns were demonstrated to identify the differences. One was a plain (planar) growth restrict mask 102 without any colloidal patterns and the other was a growth restrict mask 102 with the above-mentioned colloidal patterns.

FIG. 2(c) shows an AFM image and two panchromatic CL microscopy images (30 kV, 1.6 nA) of the ELO III-nitride layers 105, when the planar growth restrict mask 102 without any colloidal patterns was used. CL microscopy image (I) shows the open region 109 and the wings of the ELO III-nitride layers 105, wherein the AFM image is of a portion of CL microscopy image (I), and CL microscopy image (II) shows the defects in the open region 109 and no defects in the wings of the ELO III-nitride layers 105.

FIG. 2(d) shows an AFM image and two panchromatic CL microscopy images of the ELO III-nitride layers 105, wherein the growth restrict mask 102 with colloidal patterns was used. CL microscopy image (III) shows the open region 109 and the wings of the ELO III-nitride layers 105, wherein the AFM image is of a portion of CL microscopy image (III), and CL microscopy image (IV) shows the defects in the open region 109 and no defects in the wings of the ELO III-nitride layers 105.

FIG. 2(e) shows AFM scans of the growth restrict mask 102 with colloidal patterns.

FIG. 2(f) shows a microscope image of the ELO III-nitride layers 105 grown on the growth restrict mask 102 with colloidal patterns, and AFM scans of a portion of the ELO III-nitride layers 105.

In the AFM scans of FIGS. 2(e) and 2(f), the PhC pattern defined by colloids has a triangular lattice structure with a size in the sub-wavelength rage of the desired visible region (400 nm-700 nm).

Next, parallel stripes formed by etching the growth restrict mask 102 and colloids 201 comprise the opening areas 103, as shown in Step 3 of FIG. 2(a). Then, a III-nitride ELO layer 105 is grown using MOCVD and allowed to spread on the patterned growth restrict mask 102, followed by the III-nitride-based semiconductor device 107 layers, such as MQW 202, as shown in Step 4 of FIG. 2(a).

The experimental demonstration of Step 4 can be seen in FIGS. 2(c) and 2(d), where images (I) and (III) are the epilayers grown on a planar growth restrict mask 102 and a patterned growth restrict mask 102, respectively. Also, illustrations of the open window and the wings are drawn on the epilayers for better understanding. The AFM scans of the top surface morphology are shown in the sideward windows.

Panchromatic CL measurements revealed threading dislocations (TDs) on the epitaxial layers are shown in images (II) and (IV) for the planar growth restrict mask 102 and the patterned growth restrict mask 102 respectively. As can be seen, all the dislocations (defects) appeared along the open windows of the epitaxial layers 105 and no visible defects have been identified on the wings in both cases, which indicates a better crystal quality for the wings.

Thus, when devices 107 are made on these wings, their IQE will be improved, and thereby the lifetimes of the devices 107. Less defect density crystalline layers, like the above, also help in maintaining the spectral purity of the devices 107 when high carrier injections are introduced. That emission wavelength spread, in general terms called full width half maximum (FWHM), will not increase as found in conventional devices made on planar substrates.

As can be seen in FIGS. 2(c) and 2(d), for images (II) and (IV), even though there were PhC patterns beneath the ELO III-nitride layers 105, the quality of the wing in terms of dislocations and surface morphology is similar to the ELO III-nitride 105 grown on the no-pattern growth restrict mask 102.

The inventors confirmed successful transfer of the PhC patterns onto the growth restrict mask 102 and onto the interface 111 of the ELO layers 105, as shown in FIGS. 2(e), 2(f), 2(g) and 2(h), where the ELO layers 105 are removed from the host substrate 101 using the methods described in [S. Gandrothula, Appl. Phys. Express 13, 041003 (2020)].

An interface of the ELO layers 105 was experimentally scanned using AFM and the results can be found in FIGS. 2(e), 2(f), 2(g) and 2(h) as an epilayer interface. The pattern on the interface of the ELO layer 105 is copied from the pattern on the growth restrict mask 102.

FIG. 2(i) is a collection of microscope, SEM and AFM images of the front and backside of the III-nitride ELO layers 105 for a planar growth restrict mask 102 and a patterned growth restrict mask 102 when different colloidal sizes were used to create the patterns. Specifically, images 203 are microscope images showing the colloid particle size; images 204 are microscope images of the backside of the ELO III-nitride layers 105; images 205 are SEM images of the backside of the ELO III-nitride layers 105; images 206 are AFM scans of the backside of the ELO III-nitride layers 105; and images 207 are AFM scans of the patterns on the growth restrict mask 102.

### Second Embodiment

A second embodiment is about realizing highly efficient LEDs of macro-size for solid-state lighting applications, such as residential, automotive, entertainment, etc. The device 107 layers, entirely grown in MOCVD, with an approximately ˜ 0.05 mm²-0.1 mm² area, are created on the wings of the ELO layers 105. For this to happen, the entire area of the growth restrict mask 102 is covered with PhC patterns, such as shown in FIG. 1(b), comprising either a hybrid mask 102A or a patterned mask 102B, and then III-nitride epitaxial layers 105 are grown using MOCVD. A mesa is etched for the LED, metal contacts are deposited, and then the LED is extracted from the host substrate 101 and packaged.

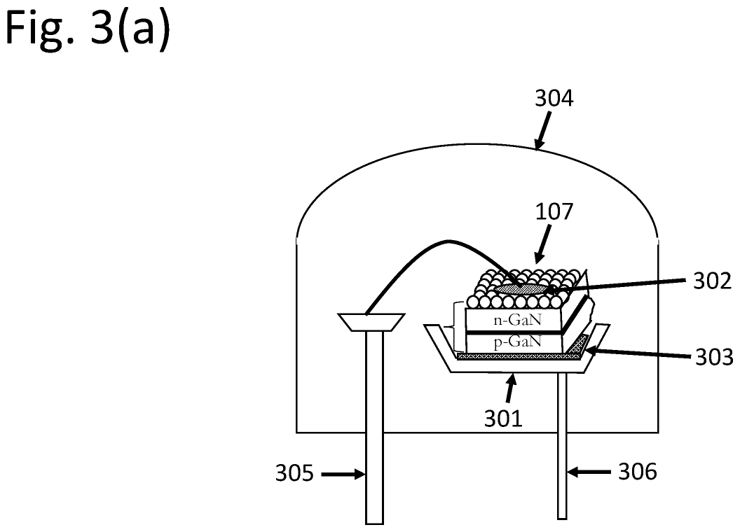

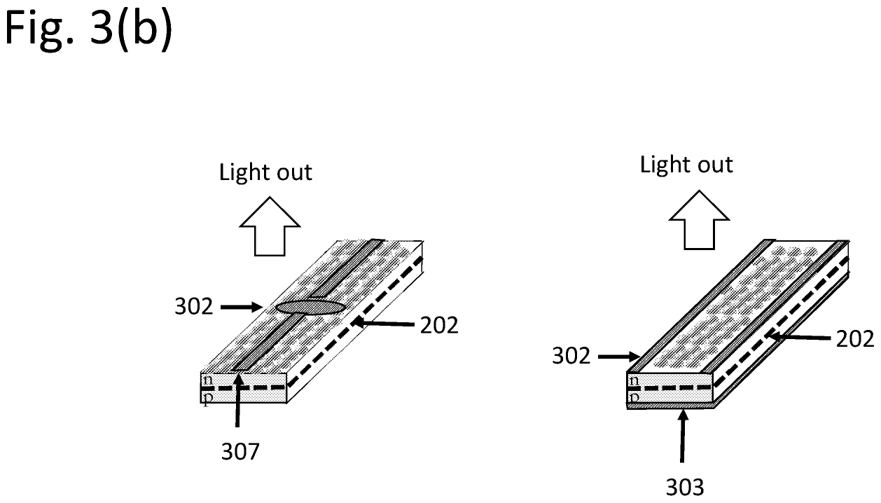

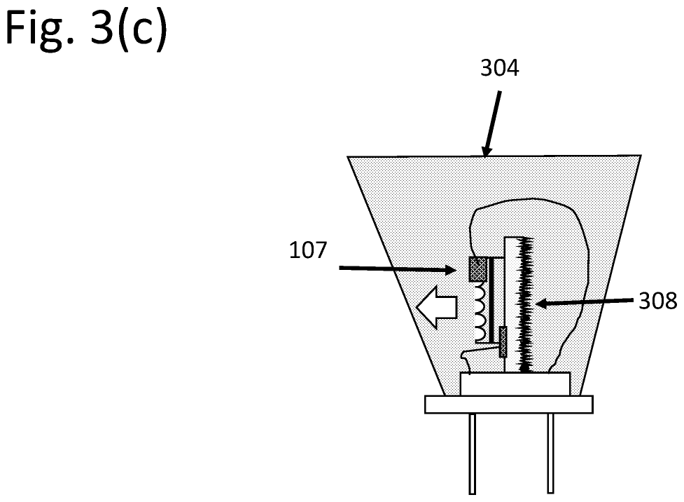

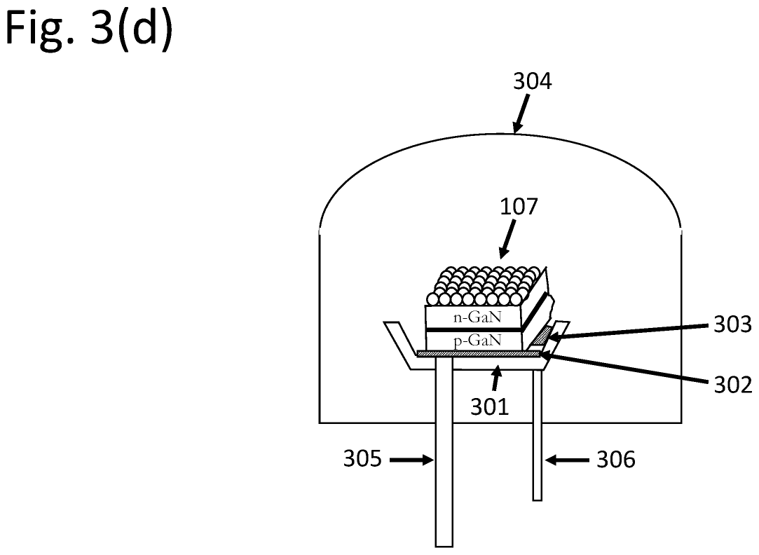

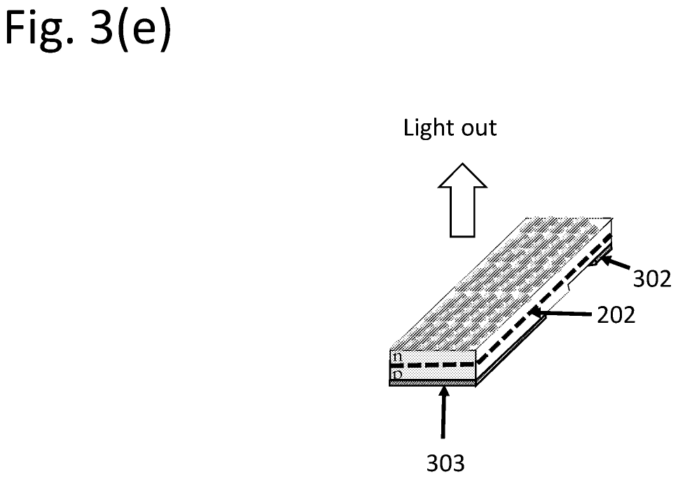

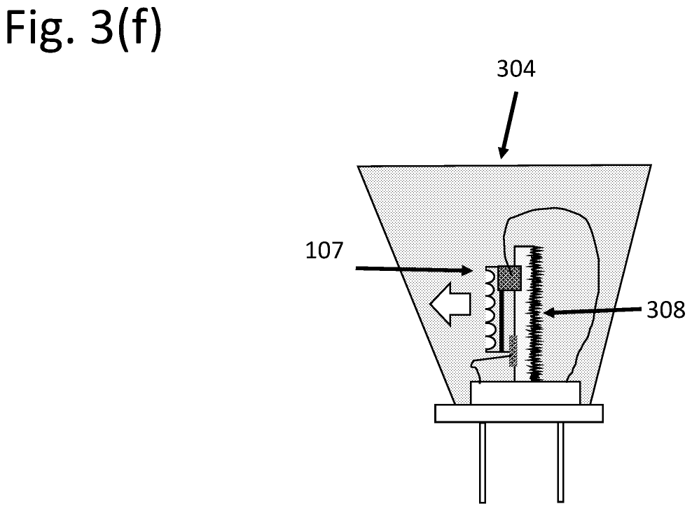

As shown in FIGS. 3(a), 3(b), 3(c), 3(d), 3(e) and 3(f), the LED can be packaged in several different ways depending on the pad configuration and/or mounting methods.

FIGS. 3(a), 3(b) and 3(c) illustrate a vertical pad configuration, wherein the device 107 resides on a cup reflector 301, and one of the metal contacts 302 is placed on the extraction features when a PhC patterned mask 102B is used, or on the flat regions 104A alongside the extraction features 104B when a hybrid-mask 102A is used. Another metal contact 303 is placed on the bottom of the device 107. All of these elements are then encapsulated in an epoxy dome 304, with a cathode 305 and anode 306 extending outside the dome 304, for electrical connection to a power source (not shown).

FIG. 3(b) also shows the extraction of light from the extraction features, along with the MQW 202, contacts 302, 303 and current spreading lines 307.

FIG. 3(c) shows a ZnO submount 308 with backside roughening used to mount the device 107 within the dome 304, after the substrate 101 has been removed from the device 107.

FIGS. 3(d), 3(e) and 3(f) illustrate a lateral pad configuration, where the device 107 resides on a cup reflector 301, and both of the metal contacts 302 are placed on the bottom of the device 107. All of these elements are then encapsulated in an epoxy dome 304, with a cathode 305 and anode 306 extending outside the dome 304 for electrical connection to a power source (not shown). In this embodiment, the metal contacts 302, 303 are placed on a side of the device 107 opposite from the light extraction features when a PhC patterned mask 102B is used, or when a hybrid mask 102A is used.

FIG. 3(f) shows a ZnO submount 308 with backside roughening used to mount the device 107 within the dome 304, after the substrate 101 has been removed.

### Third Embodiment

A third embodiment is directed to PhC cavity micro-sized LEDs for display applications.

Next-generation displays, such as micro-light-emitting diode displays, have been researched intensively, due to their advantages of high wall-plug efficiency and wide color gamut, as compared to conventional LCDs and OLED displays. However, there are several issues with conventional thick LEDs, such as color mixing, color purity, temperature, and color stability. In order to solve these problems, III-nitride-based blue, green, and red PhC-cavity-LEDs are attracting more attention as potential alternatives. The advantages of PhC-cavity-LEDs include spectral purity and thermal stability, because the spectrum width and shape are determined by the overlap of the cavity mode and the InGaN QW emission. Another advantage is that the emission of PhC-cavity-LEDs is more directional than conventional LEDs. Also, PhC-cavities or PhCs on the p-side of the LED will damage the device layers or increase the operational characteristics. Researchers [Appl. Phys. Lett. 96, 031108 (2010)] have reported n-side PhCs by embedding them in the LED, but such an approach will increase the defects, and larger growth control is needed. Ideally, PhCs or PhC-cavities must be present near the light emitting region, namely, the QWs, to extract most of the escaping modes of light.

In display applications, micro-LEDs with at least one side smaller than ˜20 μm have been reported to be less efficient due to damage associated with plasma etching when defining the mesa. However, epitaxial layers having a threading dislocations density less than <10⁶ cm⁻² were found to be less resistant to damage from plasma etching.

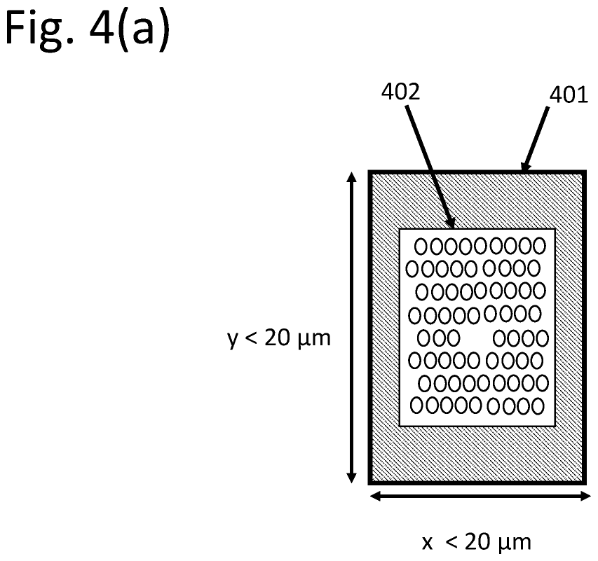

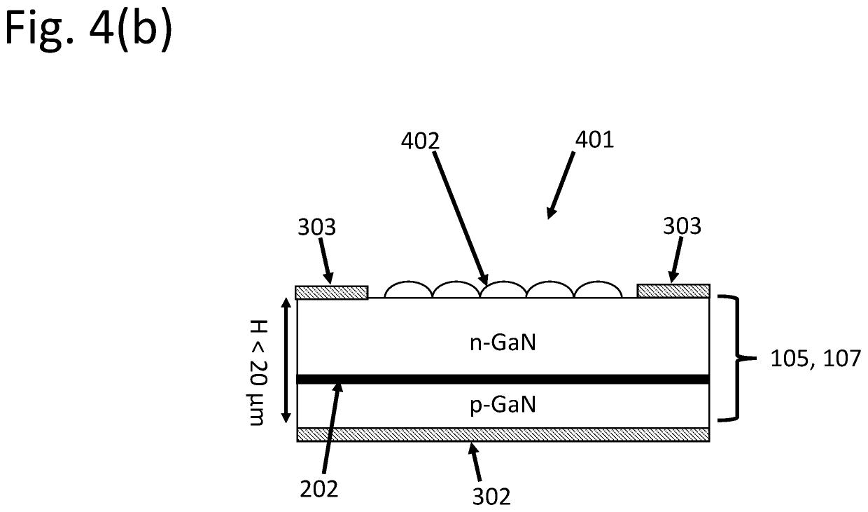

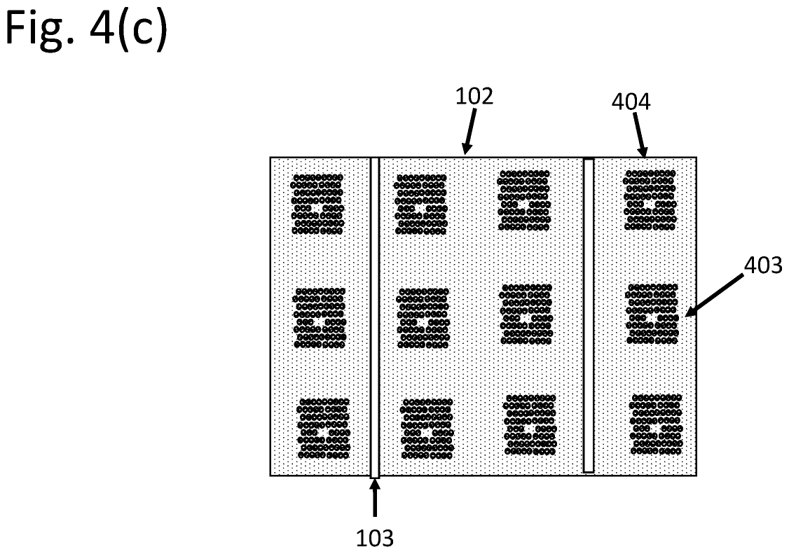

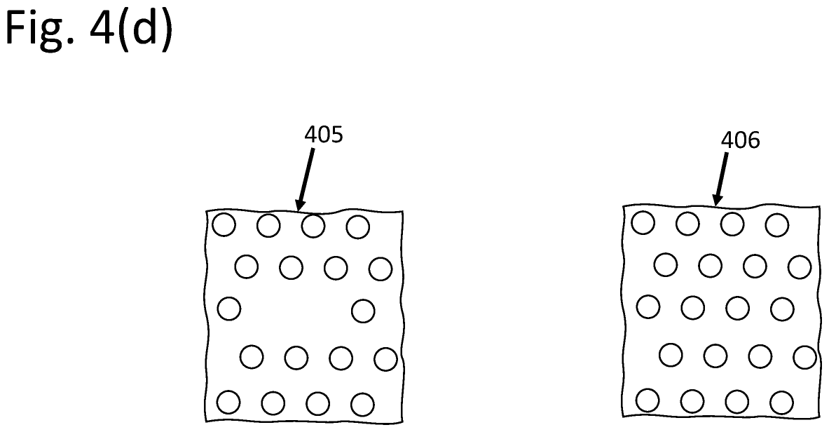

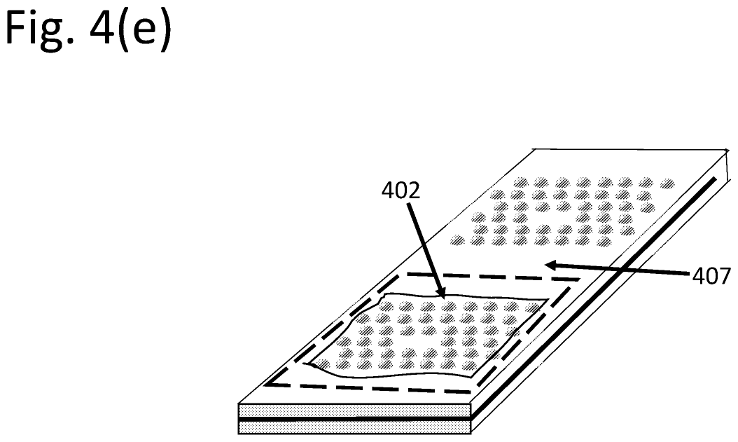

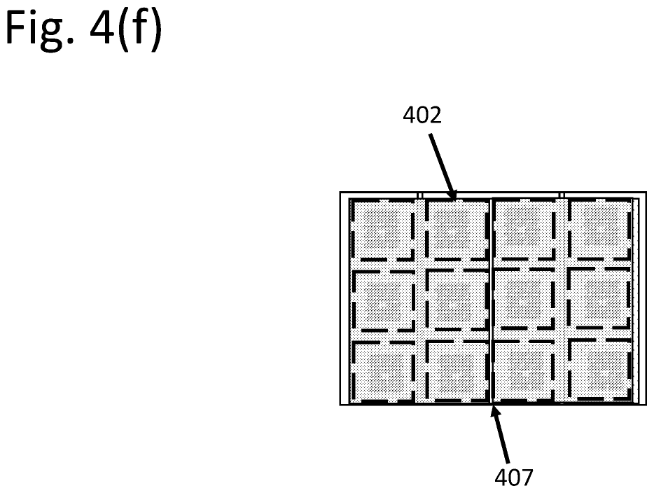

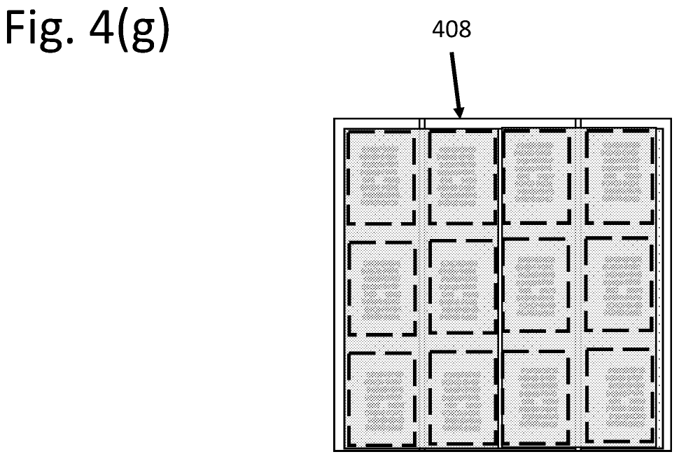

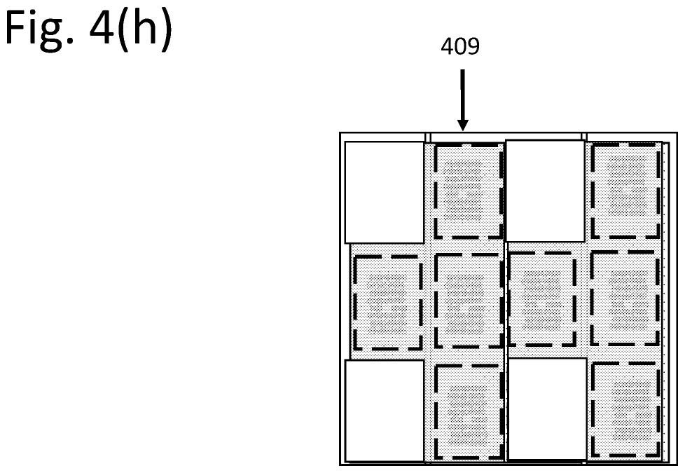

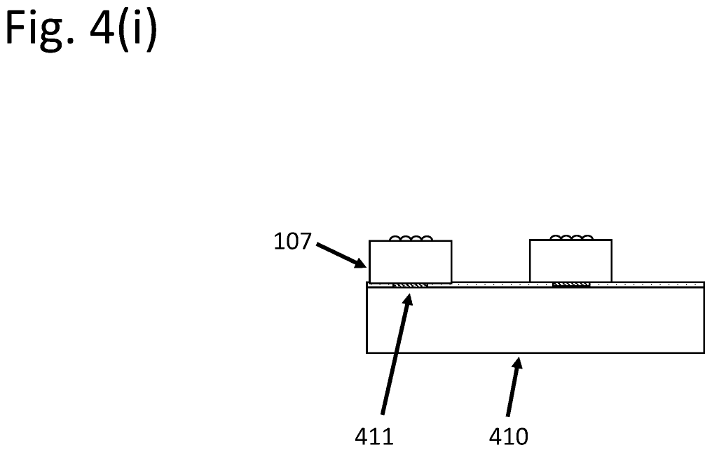

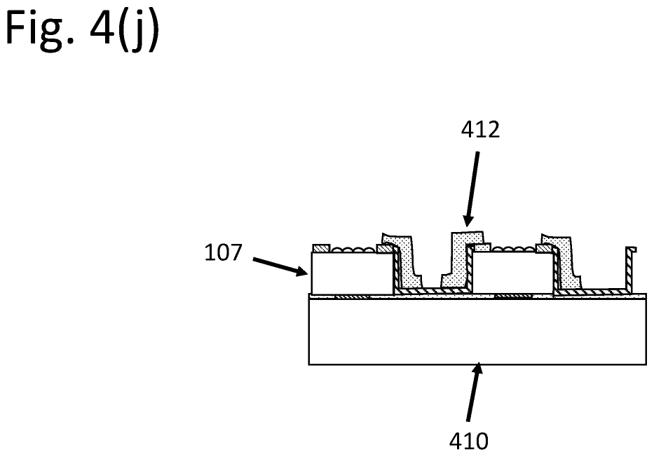

As shown in FIGS. 4(a) and 4(b), light emitting devices 401 are comprised of high crystalline quality layers on the wings of the ELO III-nitride layers 105, so that devices 401 suitable for display applications will contain substantially less or no defects. Additionally, extraction features 402, such as PhCs or PhC-cavities (for example, with disturbed PhC periodicity), can be formed on the growth restrict mask 102. The PhC-cavity-containing micro-LEDs 401 without encapsulation have x, y and h dimensions <20 μm, and can serve as light sources or pixels in display applications. The PhCs 402 act as light guiding structures and inhibit the color mixing with neighboring devices. This is a most desirable property with micro-displays that require a higher density integration of light sources, such as AR/VR applications.

As shown in FIGS. 4(c) and 4(d), a growth restrict mask 102 for PhC-cavities 403 is placed on the host substrate 101 containing an array 404 of one or more individual units of PhCs 403, wherein the PhC design can be defect-introduced PhCs 405 or regular PhCs 406.

As shown in FIGS. 4(e) and 4(f), adjacent ones of the PhCs 402 may be separated by regions 407, which may correspond to no-growth regions 106 of non-coalescence of the ELO III-nitride layers 105.

As shown in FIGS. 4(g) and 4(h), an entire bar 408 of devices 107 may be selected and separated from the substrate 101, or selected ones of the devices 409 may be selected and separated from the substrate 101.

As shown in FIGS. 4(i) and 4(j), the devices 107 may be mounted on a display panel 410 or other carrier, with bottom contacts 411 and/or top contacts 412.

This embodiment provides a solution to realize directed light sources with better quality for display applications. Also, it is nearly impossible to fabricate PhCs or PhC cavities on a conventional thin flip-chip design, as it degrades the p-side material. In addition, an approach such as thinning the substrate 101 and then placing PhCs on the substrate 101 side is time-consuming.

The method described in this application not only provides PhCs on the n-side of the device layers, but also provides device epitaxial layers with negligibly small threading dislocations.

### Fourth Embodiment

In a fourth embodiment, to maximize the vertical light extraction of PhC LEDs, it is essential to keep some distance between the light emitting active region and the light guiding features, comparable to the wavelength of light in the material. In that case, the ratio of intensities in the exiting mode relative to the guided modes is increased when compared to thick LEDs. To realize this application, the invention can be modified as follows.

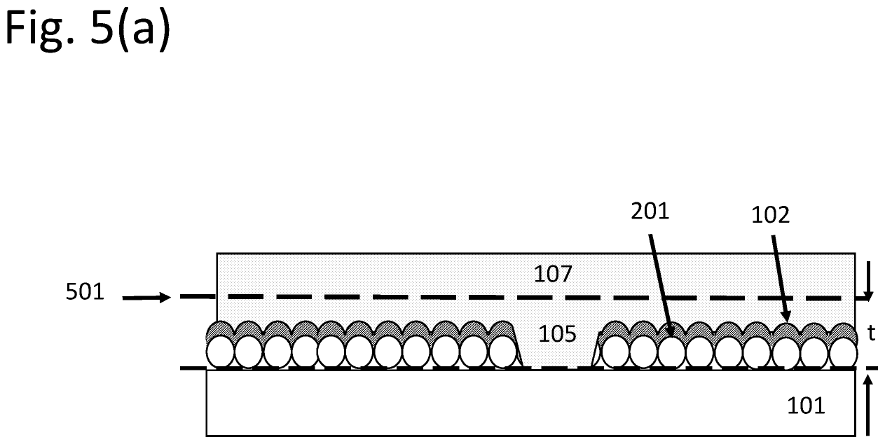

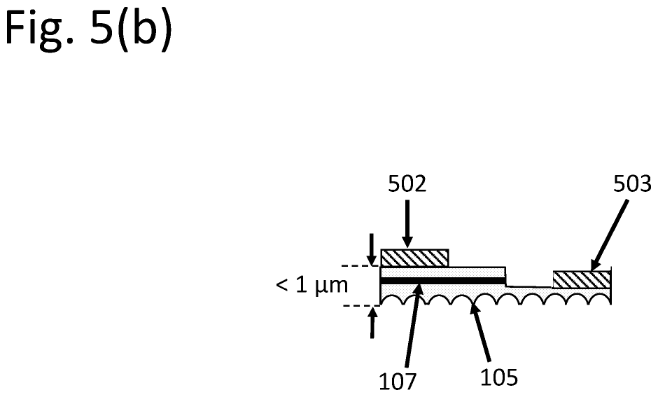

As shown in FIGS. 5(a) and 5(b), ELO III-nitride layers 105 are grown on the growth restrict mask 102 and host substrate 101, wherein light extraction features, such as PhC or a PhC-cavities formed by the colloids 201, are used to pattern the growth restrict mask 102. Then, a polish is performed on the ELO III-nitride layers 105 to a line 501, resulting in a thickness t, comprised of the thickness of the growth restrict mask 102, the colloids 201, and the ELO III-nitride layers 105 with the transferred PhC features.

Next, III-nitride-based semiconductor device 107 layers are grown on the ELO III-nitride layers 105. For example, the ELO III-nitride layers 105 may comprise one or more n-type layers, and the III-nitride-based semiconductor device 107 layers may include an n-type GaN layer, an InGaN prelayer with 5% indium content, an MQW comprised of five periods of 2.5 nm InGaN quantum wells and 13.5 nm GaN barriers as an active region, a 20 nm p-type electron-blocking layer (EBL) layer, and a 200 nm p-type GaN. The total thickness of the layers is ˜500 nm.

Finally, the substrate 101 is removed, and p- and n-contacts 502, 503 are deposited. Alternatively, p- and n-contacts 502, 503 may be deposited before removing substrate 101.

Then, similar to the other embodiments, the processed devices 107 are integrated accordingly.

### Fifth Embodiment

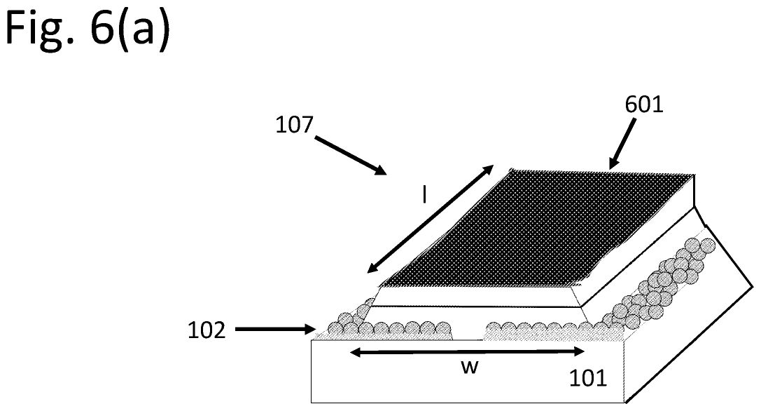

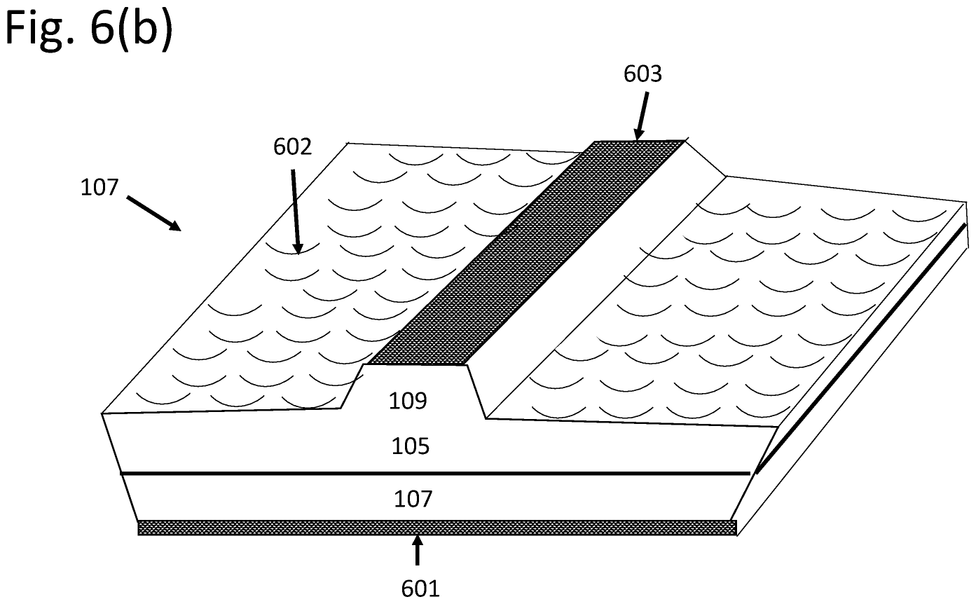

In a fifth embodiment, larger LEDs with light extraction features for better EQE are described. As shown in FIG. 6(a), after realizing an LED device 107 of desired dimensions having a length l and a width w, for example, 1×w=˜50000 μm² or more, the LED device 107, with a metallized p-contact 601 on the top of the device 107, is removed from the host substrate 101. The p-contact 601 can be a reflective material, such as Ti/Ag/Ni/Au.

As shown in FIG. 6(b), an open region 109 is a link between the ELO III-nitride layers 105 and the host substrate 101, and is a place where dislocations on the host substrate 101 still exist, but do not propagate into the wings of the ELO III-nitride layers 105. The open region 109 does not substantially contain any material from the host substrate 101. For the open region 109 region, the dislocations are >108 to 109 cm² when a GaN-on-Sapphire template is used as the host substrate 101; the dislocations are >10¹⁰ to 10¹¹ when a GaN-on-Silicon template is used as the host substrate 101; and the dislocations are 10⁶ to 10⁵ cm² when a bulk free-standing GaN substrate is used as the host substrate 101.

Also as shown in FIG. 6(b), the light extraction features 602, which may be concave, are integrated on an n-side of the LED device 107 epitaxially and the open region 109, which is a comparatively higher dislocation density region, is a planar surface that could be used to place an n-pad 603. The LED device 107 is then packaged as described above.

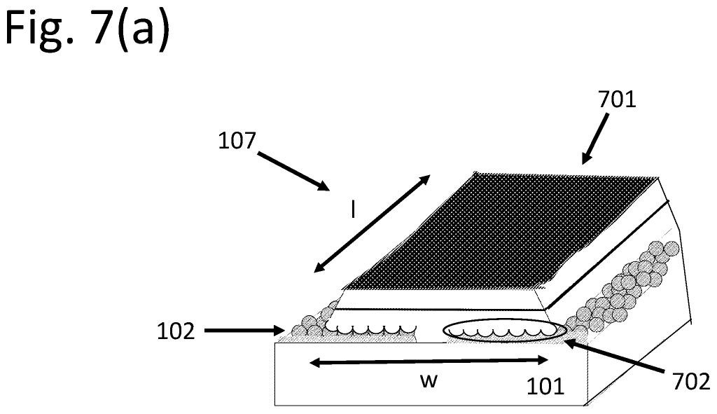

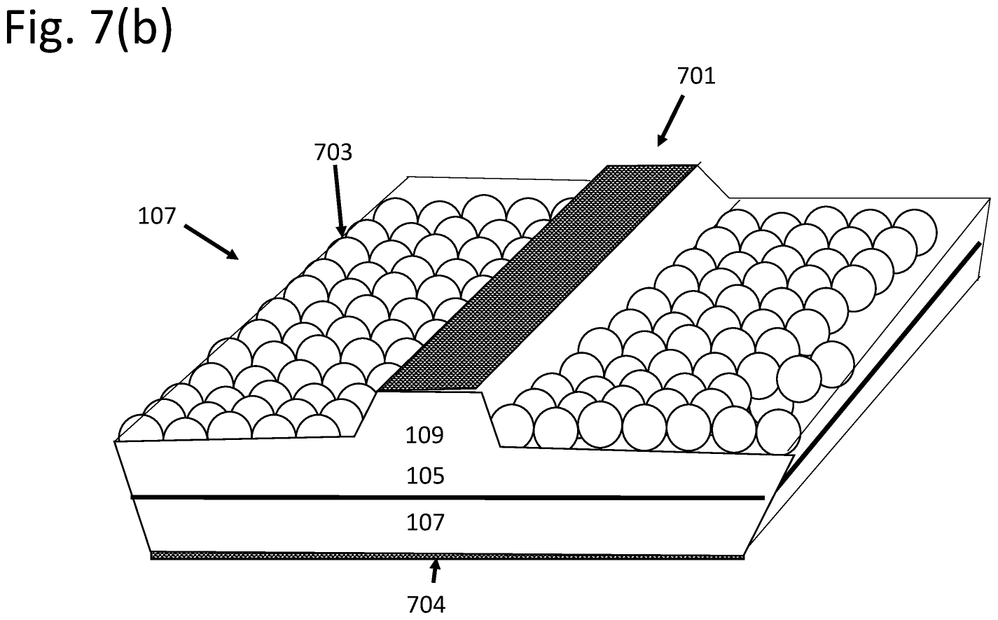

Alternatively, as shown in FIGS. 7(a) and 7(b), the LED device 107 has a metallized n-contact 701 on the open region 109, which is a comparatively higher dislocation density region, as well as a planar surface. The device 107 may include concave light extraction features 702 or convex light extraction features 703, epitaxially integrated on the n-side of the LED device 107 using the growth restrict mask 102. A metallized p-contact 704 is deposited on the open region 109, which is a comparatively higher dislocation density region, as well as a planar surface. The LED device 107 is then packaged as described above.

### Sixth Embodiment

A sixth embodiment describes the large-scale manufacturing of the integrated light extraction features for LEDs 107 onto foreign substrates 101, such as GaN-on-Sapphire, GaN-on-Si, templates on substrates, etc. The light extraction features are formed on the growth restrict mask 102 or on the foreign substrate 101. Then, the ELO III-nitride layers 105 accept the shapes of the features without adding threading dislocations to the wing of the ELO III-nitride layers 105. Macro-sized to micro-sized LEDs 107 can be fabricated, as described above.

This particular embodiment is advantageous when large dimension substrates 101, such as Sapphire (6-inches or more) or Si (12 inches or more), are used for the reduction of production costs.

Until now, conventional manufacturing of LEDs is attempted using GaN-on-Sapphire and GaN-on-Si substrates; however, there are no reports addressing the crystalline quality of the LEDs, or light extraction features near to the active region. This embodiment mainly addresses such problems.

### Process Steps

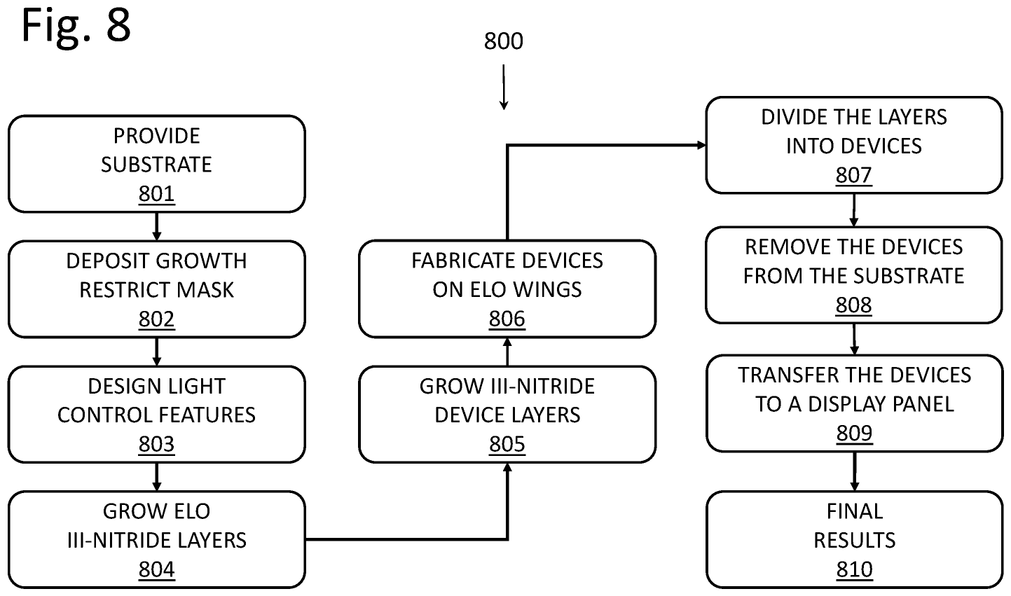

FIG. 8 is a flowchart illustrating a method 800 for fabricating semiconducting devices according to this invention. Specifically, FIG. 8 illustrates a method 800 for fabricating LEDs with epitaxial light control features.

Block 801 represents the step of providing a substrate 101. In this step, the substrate comprises a III-nitride substrate or a foreign substrate with a III-nitride template deposited thereon.

Block 802 represents the step of forming a growth restrict mask 102 on or above the substrate 101. Specifically, the growth restrict mask 102 is deposited directly on the substrate 101, or is deposited directly on the III-nitride template deposited on the substrate 101. The growth restrict mask 102 is typically an insulator film, for example, SiO₂, SiN, SiON, TiN, etc., deposited, for example, by plasma chemical vapor deposition (CVD), sputter, ion beam deposition (IBD), etc.

Block 803 represents the step of designing light control features in the growth restrict mask 102. Specifically, one or more patterns 113 are formed on the growth restrict mask 102 or the host substrate 101, using colloidal lithography, nanoimprinting, e-beam lithography, holography, or interference lithography. Preferably, the patterns 113 are formed on the growth restrict mask 102 or the host substrate 101 and then transferred epitaxially to at least an interface between the III-nitride ELO layers 105 and the growth restrict mask 104, without etching or damaging the III-nitride ELO layers 105 or the III-nitride semiconductor device 107 layers.

The patterns 113 may comprise a hybrid mask 102A that is comprised of smooth regions 104A and patterned regions 104B, or a patterned mask 102B that is comprised of patterned regions 104B without smooth regions 104A.

The patterns 113 may comprise a first designed pattern defined to enhance extraction of light emitted from the device 107 layers, for example, when the patterns 113 comprise a random rough surface, or a second designed pattern defined to enhance a directionality of light emitted from the device 107 layers, for example, when the patterns 113 comprise a PhC pattern.

In one embodiment, the patterns 113 are fabricated on the host substrate 101, the growth restrict mask 102 is formed over the patterns 113, and the growth restrict mask 102 incorporates the patterns 103, for example, when the patterns 113 comprise a PhC pattern. In this embodiment, the PhC pattern is deposited on the host substrate 101 using colloids 201; and the growth restrict mask 102 is deposited on the colloids 201, so that the growth restrict mask 102 incorporates the PhC pattern. The PhC pattern may comprise one or more PhC-cavities, the PhC-cavities may comprise an array of one or more PhCs, and the PhCs may be regular PhCs or defect-introduced PhCs.

After the patterns 113 are introduced to the growth restrict mask 102, opening areas 103 separated by stripes of the growth restrict mask 102 are etched into the growth restrict mask 102. Alternatively, the opening areas 103 may be etched into the growth restrict mask 102 before the patterns 113 are introduced into the growth restrict mask 102.

Block 804 represents the step of growing the III-nitride ELO layers 105 using ELO and the growth restrict mask 102, first from opening areas 103 in the growth restrict mask 102 and then laterally over the growth restrict mask 102, wherein the III-nitride ELO layers 105 may or may not coalesce with adjacent or neighboring III-nitride ELO layers 105.

Block 805 represents the step of growing III-nitride device 107 layers on or above the III-nitride ELO layers 105, wherein the III-nitride device 107 layers are grown on wings of the III-nitride ELO layers 105, and the III-nitride ELO layers 105 and III-nitride device 107 layers together comprise island-like III-nitride semiconductor layers 105, 107.

The patterns 113 formed on the growth restrict mask 102 or the host substrate 101 are transferred to at least an interface 111 between the III-nitride ELO layers 105 and the growth restrict mask 102, and possibly the device 107 layers as well, wherein the patterns 113 comprise epitaxially integrated light control features to extract, guide, reflect, refract, focus or defocus light emitted from the device 107 layers. Consequently, the light control features are formed before light emitting layers are formed.

In one embodiment, the light control features are formed on an n-side surface 111 of the III-nitride ELO layers 105, for example, the light control features are epitaxially integrated on a backside of the III-nitride ELO layers 105, to minimize a thickness of p-type layers of the III-nitride semiconductor device 107 layers.

Block 806 represents step of fabricating a light emitting device 107, such as an LED, on the wing region of the ELO layers 105, that is mostly covered by a flat surface region, by conventional lithography methods.

Blocks 807 represents the step of dividing the island-like III-nitride semiconductor layers 105, 107 into separate devices 107 or groups of devices 107, in order to isolate the devices 107 on the host substrate 101.

Block 808 represents the step of removing the devices 107 from the substrate 101. This may involved dissolving the growth restrict mask 102 and any protection layers using a chemical etchant, such as buffered hydrofluoric acid (BHF) or hydrofluoric acid (HF).

Block 809 represents the step of transferring the devices 107 onto a display panel, submount, or other external carrier. Specifically, this step includes transferring the devices 107 including the island-like III-nitride semiconductor layers 105, 107 to the display panel, submount, or other external carrier.

This step also includes forming a lateral injection configuration or a vertical injection configuration for injecting current into the devices 107, including depositing n- and p-contacts on the devices 107. These configurations allow each device 107 of a bar of devices 107 to be addressed separately or to be addressed together with other devices 107.

Block 810 represents the final results of the method, namely, the completed devices 107.

### REFERENCES

The following references are incorporated by reference herein:
1. Appl. Phys. Lett. 84, 855 (2004).
2. Applied Physics Express 9, 102102 (2016).
3. J. Vac. Sci. Technol., B 35, 011201 (2017).
4. U.S. Patent Application Publication No. 2017/0092810, filed Jun. 11, 2014, by James W. Raring et al., entitled “Surface morphology of non-polar gallium nitride containing substrates.”
5. Appl. Phys. Express, 13, 041003 (2020).
6. Appl. Phys. Lett. 96, 031108 (2010).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
forming a growth restrict mask on a host substrate, wherein one or more patterns are formed on the growth restrict mask or the host substrate; and
growing one or more epitaxial lateral overgrowth (ELO) layers and device layers on the host substrate using the growth restrict mask, wherein the patterns formed on the growth restrict mask or the host substrate are transferred to at least an interface between the ELO layers and the growth restrict mask, and the patterns comprise epitaxially integrated light control features to extract, guide, reflect, refract, focus or defocus light emitted from the device layers.

2. The method of claim 1, wherein the patterns are formed on the growth restrict mask or the host substrate using colloidal lithography, nanoimprinting, e-beam lithography, holography, or interference lithography.

3. The method of claim 1, wherein the patterns comprise a hybrid mask that is comprised of smooth regions and patterned regions, or a patterned mask that is comprised of patterned regions without smooth regions.

4. The method of claim 1, wherein the patterns comprise a first designed pattern defined to enhance extraction of light emitted from the device layers.

5. The method of claim 4, wherein the patterns comprise a random rough surface.

6. The method of claim 1, wherein the patterns comprise a second designed pattern defined to enhance a directionality of light emitted from the device layers.

7. The method of claim 1, wherein the patterns are fabricated on the host substrate, the growth restrict mask is formed over the patterns, and the growth restrict mask incorporates the patterns.

8. The method of claim 7, wherein the patterns comprise a photonic crystal (PhC) pattern.

9. The method of claim 8, wherein:
the photonic crystal pattern is deposited on the host substrate using colloids; and
the growth restrict mask is deposited on the colloids, so that the growth restrict mask incorporates the photonic crystal pattern.

10. The method of claim 9, wherein the photonic crystal pattern comprises one or more PhC-cavities, the PhC-cavities comprise an array of one or more PhCs, and the PhCs are regular PhCs or defect-introduced PhCs.

11. The method of claim 1, wherein the device layers are grown on one or more wings of the ELO layers.

12. The method of claim 1, wherein the patterns are formed epitaxially in the ELO layers without etching or damaging the ELO layers or the device layers.

13. The method of claim 1, wherein the light control features are formed on an n-side of the ELO layers.

14. The method of claim 13, wherein the light control features are epitaxially integrated on a backside of the ELO layers, to minimize a thickness of p-type layers of the device layers.

15. The method of claim 1, wherein the light control features are formed before light emitting layers are formed.

16. A structure, comprising:
a growth restrict mask formed on a host substrate, wherein one or more patterns are formed on the growth restrict mask of the host substrate; and
one or more epitaxial lateral overgrowth (ELO) layers and device layers grown on the host substrate using the growth restrict mask, wherein the patterns formed on the growth restrict mask or the host substrate are transferred to at least an interface between the ELO layers and the growth restrict mask, and the patterns comprise epitaxially integrated light control features to extract, guide, reflect, refract, focus or defocus light emitted from the device layers.
